(19) United States
(12) Patent Application Publication
(10) Pub. No.: US 2008/0122076 A1
(43) Pub. Date: May 29, 2008

(54) Conductive Wiring for Semiconductor Devices

(75) Inventors: Jong-Won Hong, Gyeonggi-do (KR); Gil-Heyun Choi, Seoul (KR); Jong-Myeong Lee, Gyeonggi-do (KR); Hyun Park, Gyeonggi-do (KR); Kyung-In Choi, Gangwon-do (KR); Hyun-Bae Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/943,166

(22) Filed: Nov. 20, 2007

(30) Foreign Application Priority Data
Nov. 24, 2006 (KR) 2006-116870

(51) Int. Cl. H01L 23/48

(52) U.S. Cl. 257/734

(57) ABSTRACT

A conductive wiring for a semiconductor device is provided including a semiconductor substrate and a plurality of lower conductive structures on the semiconductor substrate. An insulating layer is provided that electrically insulates the plurality of lower conductive structures from one another. A first insulation interlayer pattern is provided on the insulation layer. The first insulation interlayer pattern includes a contact plug that contacts the substrate through the insulation layer. An etch-stop layer is provided on the contact plug and the first insulation interlayer pattern. A second insulation interlayer pattern is provided on the etch-stop layer. The second insulation interlayer pattern includes a conductive line that is electrically connected to the contact plug. Related methods and flash memory devices are also provided.

### CLAIM OF PRIORITY

This application claims priority under 35 U.S.C. § 119 to Korean Patent Application No. 2006-116870, filed on Nov. 24, 2006 in the Korean Intellectual Property Office (KIPO), the content of which is hereby incorporated herein by reference as if set forth in its entirety.

### FIELD OF THE INVENTION

The present invention generally relates to semiconductor devices and, more In particular, to conductive wiring for semiconductor devices and related methods and flash memory devices.

### BACKGROUND OF THE INVENTION

Semiconductor memory devices, in general, are classified as either volatile or non-volatile memory devices. Volatile memory devices such as dynamic random access memory (DRAM) devices and static random access memory (SRAM) devices have relatively high input/output (I/O) speeds, and lose data stored therein when power is shut off. In contrast, non-volatile memory devices such as read-only memory (ROM) devices have relatively slow I/O speeds, and are able to maintain data stored therein even when power is shut off. Among the non-volatile memory devices, electrically erasable programmable ROM (EEPROM) devices or flash memory devices are becoming higher in demand. A flash memory device is a kind of an advanced EEPROM for electrically erasing data at a high speed. That is, in a flash EEPROM device, data is electrically stored, i.e., programmed or is electrically erased through a Fowler-Nordheim (F-N) tunneling mechanism and/or a channel hot electron injection mechanism.

As semiconductor devices become more highly integrated and operate at higher speeds, line widths of gate electrodes are continuously decreased and switching times become much shorter in the semiconductor devices. A decrease in the line width of a gate electrode may cause an increase in electrical resistance and a decrease in response speed in a semiconductor device, and the decrease in response speed may cause an increase in resistance-capacitance (RC) delay time. Furthermore, a shorter switching time accelerates the increase in RC delay time. Therefore, the RC delay time typically has to be improved for increasing the degree of integration of semiconductor devices. In particular, the RC delay time is rapidly increased when the design rules of semiconductor devices become lower than about 0.5 μm. As a result, a decrease in RC delay time is typically required for increasing the degrees of integration and the operation speeds of semiconductor devices because recent design rules of semiconductor devices have been decreased, for example, to about 0.18 μm and to about 0.13 μm.

The RC delay time discussed above may give rise to various problems including signal delay in a semiconductor device, such as crosstalk noise due to RC coupling caused by small line intervals between wirings and high power consumption. The signal delay caused by the RC delay and the crosstalk noise has generally been handled using two methods that respectively improve the resistance and the capacitance of a semiconductor device. With respect to the improvement of the resistance, aluminum (Al) wirings have been replaced with copper (Cu) wirings, and the electrical resistance of the copper wiring may be reduced by as much as about 37% with respect to that of the aluminum wiring. In particular, copper (Cu) has a line resistance of at most about 1.7 μΩ/cm, and thus has been widely used as a low-resistance material for the wiring in semiconductor devices. The research related to the capacitance has been directed to increasing the dielectric constant of layers in a semiconductor device. Various materials have been suggested having high dielectric constants, which are known as high-k materials.

In particular, as the integration degree of flash memory devices increases, gap distances between adjacent bit lines gradually decrease and sheet resistances R, of the bit lines gradually increase in inverse proportion to the decreasing gap distances of the bit lines in the flash memory devices. It has been suggested that an increase in the height of a bit line may reduce the sheet resistance Rs of the bit line. However, the increase in the height of the bit line may cause an increase in parasitic capacitance in a flash memory device. Thus, a variety of research has been conducted for decreasing the height of the bit line, as well as for improving the electrical resistance of the bit line using a low-resistance material in highly integrated flash memory devices.

Despite this research on the bit lines of flash memory devices, the parasitic capacitance in a bit line does not decrease in proportion to a decrease in the height of the bit line in a flash memory device. On the contrary, the parasitic capacitance increases even though the height of the bit line decreases, so that an RC delay time is also increased to thereby decrease the operation speed of the flash memory device.

Referring now to FIGS. 1 and 2, are cross-sections illustrating a bit line structure of a conventional flash memory device and a smaller bit line structure of which the structure is the same as the bit line in FIG. 1 except that the height of the bit line is smaller than that of the bit line in FIG. 1, respectively. Referring first to FIG. 1, the bit line structure of a conventional flash memory device includes a metal plug 4 penetrating through a first insulation interlayer 1, an etch-stop layer 3 on the first insulation interlayer 1, a second insulation interlayer 2 on the etch-stop layer 3, and a conductive wiring 5 in an opening in the etch-stop layer 3 and the second insulation interlayer 2 and making contact with the metal plug 4. The etch-stop layer 3 gives some information about a terminal point of the etching process against the second insulation interlayer 2 and the conductive wiring 5 functioning as a the bit line of the conventional flash memory device.

In a manufacturing process for the flash memory device, the etch-stop layer 3 including, for example, silicon nitride, has a thickness of greater than about 350 Å when a copper wiring is used as the conductive wiring (bit line) 5 of the flash memory device. In case that the etch-stop layer 3 is formed to have a small thickness of less than about 350 Å, the first insulation interlayer 1 and the metal plug 4 are also etched off simultaneously with the second insulation interlayer 2 in the etching process. In particular, the silicon nitride layer does not function as the etch-stop layer with respect to the etching process against the second insulation interlayer 2. Furthermore, when another etching process is performed against the etch-stop layer 3 to thereby form the opening, the first insulation interlayer 1 is over-etched to a depth from an upper surface of the metal plug 4 in consideration of contaminant removal and the difference of an etching rate between the first insulation interlayer 1 and the metal plug 4, to thereby form an over-etched portion Eₒᵥₑᵣ around the metal plug 4. The depth of the over-etched portion Eₒᵥₑᵣ is about 150 Å in a manufacturing process for the flash memory device.

Accordingly, when a total thickness of the bit line 5 of the conventional flash memory device is about 1,100 Å, an oxide layer in the flash memory device has a thickness of about 750 Å, and a nitride layer, which has a relatively high dielectric constant in the flash memory device, has a thickness of about 350 Å. The oxide layer includes the over-etched portion Eₒᵥₑᵣ of the first insulation interlayer 1 and the second insulation interlayer 2 that is formed on the etch-stop layer 3, and electrically isolates the bit line 5 from surroundings, and the nitride layer includes etch-stop layer 3 between the first and second isolation interlayer 2 and 3. Accordingly, the oxide layer encloses about 70% of the bit line 5 and the nitride layer encloses about 30% of the bit line 5. As a result, reduction of the total thickness of the bit line 5 sufficiently decreases the parasitic capacitance between adjacent bit lines 5 in the flash memory device. Hereinafter, the contact portion of the bit line enclosed by the oxide layer is referred to as an oxide contact portion, and the contact portion of the bit line enclosed by the nitride layer is referred to as a nitride contact portion. Furthermore, the oxide contact portion with respect to the whole bit line is referred to as an oxide contact ratio, and the nitride contact portion with respect to the whole bit line is referred to as a nitride contact ratio. That is, the oxide contact ratio is about 70% and the nitride contact ratio is about 30% in the above conventional bit line structure having a thickness of about 1,100 Å.

However, when the bit line is excessively reduced below a critical point and a total thickness of the reduced bit line 5a of FIG. 2 is less than a marginal thickness, the nitride contact portion still remains unchanged, while the oxide contact portion of the bit line is remarkably reduced, as illustrated in FIG. 2. As a result, the nitride contact ratio is significantly increased and the parasitic capacitance between adjacent bit lines is increased although the total thickness of the bit line is reduced.

For example, when the bit line is reduced to a total thickness of about 600 Å, the second insulation interlayer 2 is reduced to a thickness of about 100 Å as illustrated in FIG. 2, because the depth of the over-etched portion Eₒᵥₑᵣ of the first insulation interlayer 1 and the thickness of the etch-stop layer 3 remains unchanged. Accordingly, the oxide contact portion of the bit line 5 is reduced to a thickness of about 250 Å, and thus the oxide contact ratio is reduced to about 40% with respect to the total thickness of about 600 Å.

Accordingly, a much larger portion of the reduced bit line 5a makes contact with the etch-stop layer 3 of which the dielectric constant is larger than that of the insulation interlayer, and the nitride contact ratio approaches about 60% with respect to the total thickness of the reduced bit line 5a. As a result, an increase of the parasitic capacitance due to an increase of the dielectric constant is much greater than a decrease of the parasitic capacitance due to the reduction of the total thickness of the bit line, so that an overall parasitic capacitance of the reduced bit line 5a increases despite the reduction of the thickness thereof.

As discussed above, the increase in the parasitic capacitance of the bit line may cause a decrease in the response speed of the device and an increase in RC delay time, opposite to recent technical trends of semiconductor devices. Accordingly, the improvement in the operation performance of a flash memory device by the reduction of the total thickness of a bit line typically requires a reduction of the nitride contact ratio with respect to the overall thickness of the bit line as well as the thickness reduction of the bit line.

### SUMMARY OF THE INVENTION

Some embodiments of the present invention provide a conductive wiring for a semiconductor device including a semiconductor substrate and a plurality of lower conductive structures on the semiconductor substrate. An insulating layer is provided that electrically insulates the plurality of lower conductive structures from one another. A first insulation interlayer pattern is provided on the insulation layer. The first insulation interlayer pattern includes a contact plug that contacts the substrate through the insulation layer. An etch-stop layer is provided on the contact plug and the first insulation interlayer pattern. A second insulation interlayer pattern is provided on the etch-stop layer. The second insulation interlayer pattern includes a conductive line that is electrically connected to the contact plug.

In further embodiments of the present invention, the first insulation interlayer pattern may include at least one of borophosphosilicate (BPSG), phosphosilicate glass (PSG), fluorosilicate glass (FSG), plasma-enhanced tetraethylorthosilicate (PE-TEOS) and undoped silicate glass (USG). In certain embodiments of the present invention, the contact plug may include a single layer including a polysilicon layer or a metal layer or a multilayer including the polysilicon layer and the metal layer sequentially stacked. The metal layer may include a tungsten (W) layer or an aluminum (Al) layer.

In further embodiments of the present invention, the first insulation interlayer pattern may have a thickness of from about 4,000 Å to about 5,000 Å on a surface of the substrate.

In some embodiments of the present invention, the etch-stop layer may include carbon (C) or nitrogen (N) implanted into surfaces of the first insulation interlayer pattern and the contact plug. The etch-stop layer may include at least one of silicon carbide (SiC), silicon nitride (SiN), silicon oxynitride (SiON) and silicon oxycarbide (SiOC) and may have an etching selectivity with respect to the second insulation interlayer pattern. The contact plug may protrude from a surface of the first insulation interlayer pattern such that the etch-stop layer is discontinuous at a boundary portion of the first insulation interlayer pattern and the contact plug.

In further embodiments of the present invention, the etch-stop layer may have a thickness of from about 50 Å to about 200 Å from a surface of the first insulation interlayer pattern.

In still further embodiments of the present invention, the second insulation interlayer pattern may include at least one of BPSG, PSG, FSG, PE-TEOS, and USG. The second insulation interlayer pattern may include a same material as the first insulation interlayer pattern.

In some embodiments of the present invention, the conductive line may include copper (Cu), tungsten (W) and/or aluminum (Al). The second insulation interlayer pattern may include a single damascene pattern.

In further embodiments of the present invention, the conductive line may have a thickness of from about 400 Å to about 700 Å from a surface of the etch-stop layer, and a surface of the conductive line may be coplanar with that of the second insulation interlayer pattern.

In still further embodiments of the present invention, the substrate may include a device isolation layer defining an active region that extends in a first direction. The plurality of lower conductive structures may include a string selection transistor, a plurality of cell selection transistors and a ground selection transistor on an active region of the semiconductor substrate such that the string selection transistor, the plurality of the cell selection transistors, and a plurality of the ground selection transistors are arranged along a second direction perpendicular to the first direction to thereby function as a string selection line (SSL), a plurality of word lines (WLs) and a ground selection line (GSL) of a flash memory device, respectively

Although some embodiments of the present invention including conductive wirings are discussed above, related methods and flash memory devices are also provided herein.

### BRIEF DESCRIPTION OF THE DRAWINGS

FIG. 1 is a cross-section illustrating a bit line structure of a conventional flash memory device.

FIG. 2 is a cross-section illustrating a smaller bit line structure of which the structure is the same as the bit line in FIG. 1 except that the height of the bit line is smaller than that of the bit line in FIG. 1.

FIG. 3 is a cross-section illustrating a conductive wiring for a semiconductor device in accordance with some embodiments of the present invention.

FIG. 4 is a cross-section illustrating a conductive wiring in accordance with some embodiments of the present invention.

FIGS. 5A to 5H are cross-sections illustrating processing steps in the fabrication of the semiconductor device of FIG. 3 in accordance with some embodiments of the present invention.

FIGS. 6A to 6C are cross-sections illustrating processing steps in the fabrication of the semiconductor device of FIG. 4 in accordance with some embodiments of the present invention.

FIG. 7 is a plan view illustrating a flash memory device in accordance with some embodiments of the present invention.

FIG. 8A is a cross-section taken along the line I-I′ of the flash memory device illustrated in FIG. 7 in accordance with some embodiments of the present invention.

FIG. 8B is a cross-section taken along the line II-II′ of the flash memory device illustrated in FIG. 7 in accordance with some embodiments of the present invention.

FIGS. 9A to 13B are cross-sections illustrating processing steps for manufacturing a flash memory device including the conductive line illustrated in FIG. 3 in accordance with some embodiments of the present invention.

FIGS. 14A to 15B are cross-sections illustrating processing steps for manufacturing a flash memory device including the conductive line illustrated in FIG. 4 in accordance with some embodiments of the present invention.

FIG. 16 is a graph illustrating variation of an effective dielectric constant K_{eff} of the flash memory device in relation to the thickness of the bit line including the etch-stop layer including silicon nitride (SiN) in accordance with some embodiments of the present invention.

FIG. 17 is a graph showing variation of an effective dielectric constant K_{eff} of the flash memory device in relation to the thickness of the bit line including the etch-stop layer including silicon nitride (SiN) and silicon carbide (SiC) in accordance with some embodiments of the present invention.

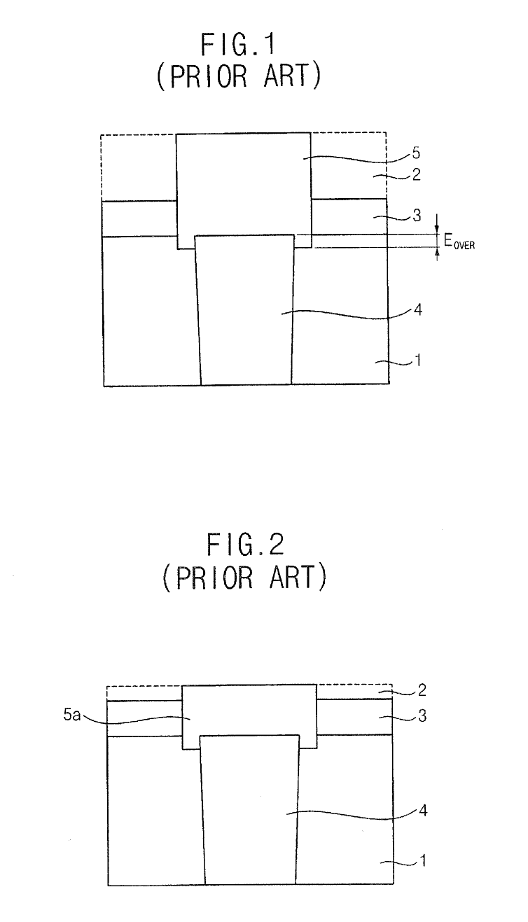

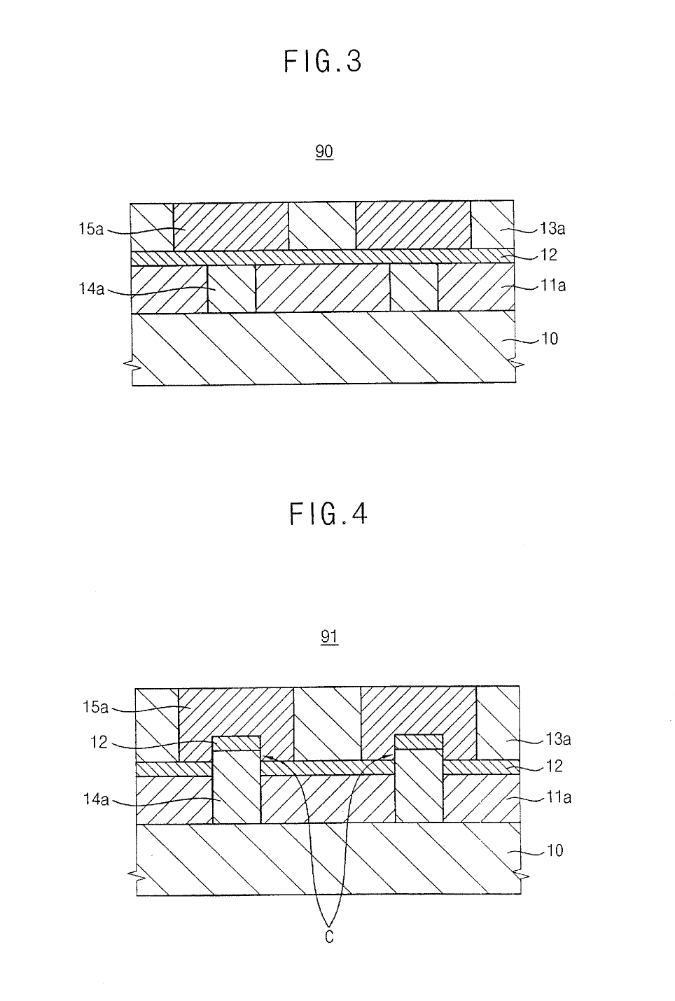

### DETAILED DESCRIPTION OF EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

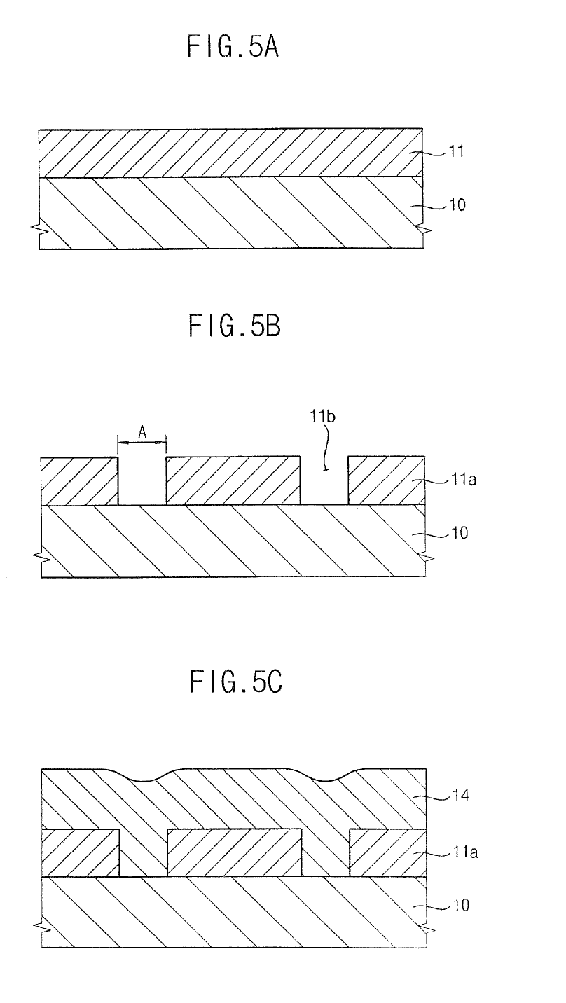

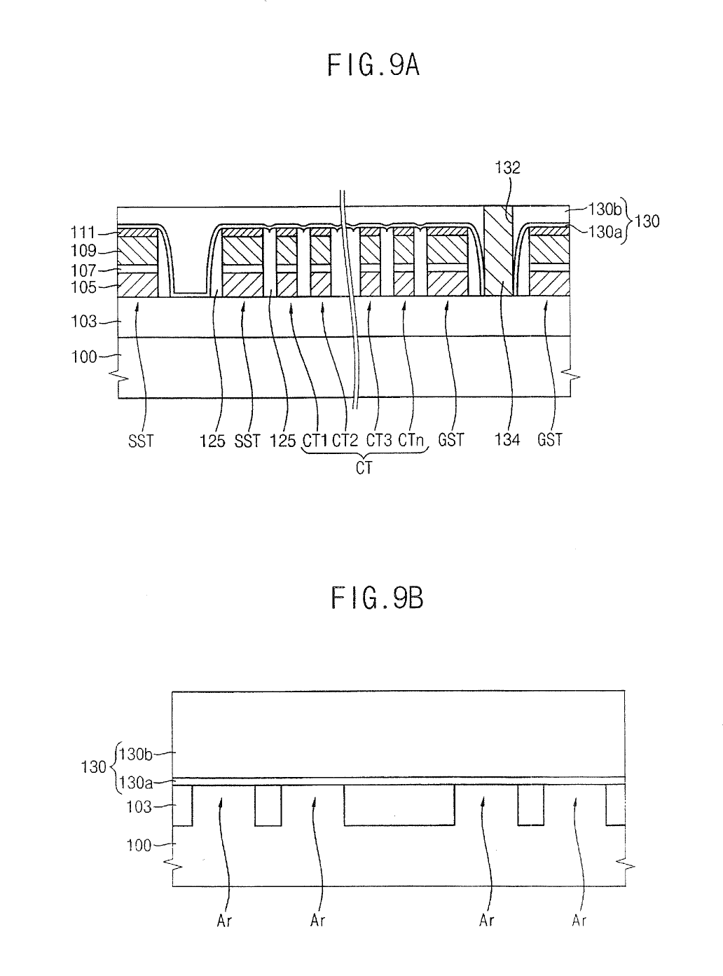

Some embodiments of the present invention will now be discussed with respect to FIGS. 3 through 17. Referring first to FIG. 3, a cross-section illustrating a conductive wiring for a semiconductor device in accordance with some embodiments of the present invention will be discussed. As illustrated in FIG. 3, a conductive wiring 90 for a semiconductor device includes a semiconductor substrate 10 on which various lower structures for a semiconductor device, such as a transistor and a capacitor are formed, first and second insulation interlayer patterns 11a and 13a sequentially stacked on the substrate 10, an etch-stop layer 12 between the first and second insulation interlayer patterns 11a and 13a, a contact plug 14a in the first insulation interlayer pattern 11a and a conductive line 15a electrically connected to the contact plug 14a.

In some embodiments of the present invention, the substrate 10 includes an operation unit structure of a flash memory device having a string selection transistor (not shown), a plurality of cell transistors, and a ground selection transistor (not shown), so that a drain region of the string selection transistor is electrically connected to a contact plug for a bit line, and a source region of the ground selection transistor is electrically connected to a common source line. In certain embodiments of the present invention, the substrate 10 may include an operation unit structure of a dynamic random access memory (DRAM) device having a transistor and a capacitor as would be known to one of ordinary skill in the art.

The first insulation interlayer pattern 110a may electrically insulate the contact plug 14a and the lower structures on the substrate 10 from each other, and may protect the lower structures from damage in subsequent processes for forming the contact plug 14a and the conductive line 15a. Furthermore, adjacent contact plugs 14a are electrically insulated from each other by the first insulation interlayer pattern 11a. In some embodiments of the present invention, the first insulation interlayer pattern 11a may include an oxide pattern, for example, borophosphosilicate (BPSG), phosphosilicate glass (PS G), fluorosilicate glass (FS G), plasma-enhanced tetraethylorthosilicate (PE-TEOS), undoped silicate glass (USG) or any combination thereof. In some embodiments of the present invention, insulation interlayer pattern 11a may include PE-TEOS, and is formed on the substrate to a thickness of from about 4,000 Å to about 5,000 Å using, for example, a plasma-enhanced chemical vapor deposition (PECVD) process using tetraethoxysilane (Si(OC₂H₅)₄) gas and oxygen (O₂) or ozone (O₃) gas as source gases.

A contact hole is positioned in the first insulation interlayer pattern 11a, and the substrate 10 is partially exposed through the contact hole. The contact plug 14a is positioned in the contact hole, and the conductive line 15a and the substrate 10 is electrically connected with each other through the contact plug 14a. A top surface of the contact plug 14a is coplanar with a top surface of the first insulation interlayer pattern 11a, so that the top surfaces of the contact plug 14a and the first insulation interlayer pattern 11a are configured to be a flat plane. In some embodiments of the present invention, the contact plug 14a may include a single layer, such as a polysilicon layer and a metal layer including, for example, tungsten (W) or aluminum (Al), or a multilayer in which the polysilicon layer and the metal layer are stacked on the substrate 10. In embodiments of the present invention where the contact plug 14a includes a tungsten (W) layer, a titanium (Ti) layer or a titanium nitride (TiN) layer may be further included between the contact plug 14a and the first insulation interlayer pattern 11a and between the contact plug 14a and the substrate 10, so that electrical resistance may be decreased at a boundary surface of the contact plug 14a.

The etch-stop layer 12 is positioned on the flat top surfaces of the first insulation interlayer pattern 11a and the contact plug 14a, and the second insulation interlayer pattern 13a is positioned on the etch-stop layer 12.

Adjacent conductive lines 15a are electrically insulated from each other by the second insulation interlayer pattern 13a. The conductive line 15a is electrically connected to a specific contact plug 14a, and other contact plugs 14a except for the specific contact plug are electrically insulated from the conductive line 15a by the second insulation interlayer pattern 13a.

In some embodiments of the present invention, the second insulation interlayer pattern 13a may also include an oxide pattern, for example, BPSG, PSG, FSG, PE-TEOS, USG or any combination thereof. The second insulation interlayer pattern 13a may not necessarily include the same material as the first insulation interlayer pattern 11a. However, in some embodiments of the present invention, the second insulation interlayer pattern 13a may include PE-TEOS like the first insulation interlayer pattern 11a. In other words, the second insulation interlayer pattern 13a is formed on the etch-stop layer 12 to a thickness of from about 400 Å to about 700 Å by a PECVD process using tetraethoxysilane (Si(OC₂H₅)₄) gas and oxygen (O₂) or ozone (O₃) gas as source gases.

A via hole (not shown) is positioned in the second insulation interlayer pattern 13a, and the contact plug 14a is partially exposed through the via hole. The conductive line 15a including a conductive material is positioned in the via hole. In some embodiments of the present invention, the second insulation interlayer pattern 13a including the via hole is formed by a single damascene process, and the conductive line 15a in the via hole is connected to the contact plug 14a in the contact hole. In the single damascene process, the etch-stop layer 12 determines a terminal point of an etching process for forming the via hole in the second insulation interlayer pattern 13a. In particular, the etching process in the single damascene process is performed to the terminal point at which the etch-stop layer is exposed, so that the via hole is formed into a cylindrical shape of which the height is substantially the same as the thickness of the second insulation interlayer pattern 13a.

Accordingly, the etch-stop layer 12 may include a material having an etching selectivity with respect to the second insulation interlayer pattern 15a. Example materials of the etch-stop layer 12 may include silicon carbide (SiC), silicon nitride (SiN), silicon oxynitride (SiON), silicon oxycarbide (SiOC) or any combination thereof. In some embodiments of the present invention, the etch-stop layer has a thickness of from about 50 Å to about 200 Å by an ion implantation process against the flat top surfaces of the first insulation interlayer pattern 11a and the contact plug 14a. The ion implantation process may allow the etch-stop layer 12 to be formed atom by atom or molecule by molecule, so that the etch-stop layer 12 may have a reduced thickness without substantial deterioration of a layer density. Accordingly, a thickness ratio of the etch-stop layer with respect to the insulation interlayer patterns 11a and 13a may decrease by the ion implantation process, thereby possibly reducing the parasitic capacitance caused from the etch-stop layer 12 having a dielectric constant relatively higher than the insulation interlayer pattern 11a and 13a. In other words, the likelihood that the parasitic capacitance may increase is reduced despite the thickness reduction of the conductive line 15a. Furthermore, although the thickness of the etch-stop layer 12 is reduced by the ion implantation process, the etch-stop layer 12 still has the layer density sufficient for terminating the etching process in the single damascene process.

A gas cluster ion beam (GCIB) process may be further performed on the etch-stop layer 12 after completing the ion implantation process, thereby possibly improving the surface uniformity and the layer density of the etch-stop layer 12. In the above GCIB process, an energy state of each atom in an accelerated gas cluster approximates to an individual bonding energy of a surface of the substrate 10.

The etch-stop layer 12 may also be formed on the first insulation interlayer pattern 11a and the contact plug 14a by a closed molding process such as a surface infusion or an inter-laminar infusion to the top surfaces of the first insulation interlayer pattern 11a and the contact plug 14a. In some embodiments of the present invention, carbon (C) atoms, nitrogen (N) atoms or molecules including carbon or nitrogen atoms may be infused onto the flat top surfaces of the first insulation interlayer pattern 11a and the contact plug 14a by the ion implantation process or the surface infusion process, thereby forming a thin layer, which has an etching selectivity with respect to the second insulation interlayer pattern 13a, on the top surfaces of the first insulation interlayer pattern 11a and contact plug 14a.

The conductive line 15a in the via hole may include a conductive metal, and an electrical signal is transferred to the substrate 10 from the conductive line 15a through the contact plug 14a. Examples of the conductive material may include copper (Cu), tungsten (W), aluminum (Al) and any combination thereof. In some embodiments of the present invention, the conductive line 15a may include copper (Cu), and has substantially the same thickness as the second insulation interlayer pattern 13a in a range of from about 400 Å to about 700 Å.

According to the conductive line for a semiconductor device, the etch-stop layer 12 between the first and second insulation interlayer patterns 11a and 13a may have a sufficiently reduced thickness without substantial deterioration of layer density due to an ion implantation process. Therefore, although the overall thickness of the conductive line 15a is decreased, the parasitic capacitance caused by the etch-stop layer 12 may be reduced.

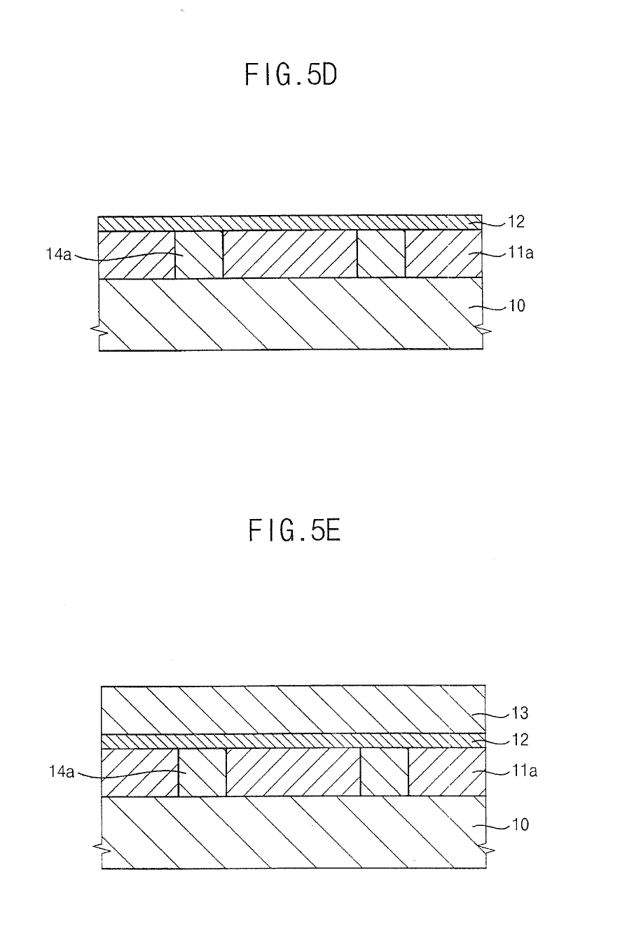

Referring now to FIG. 4, a cross-section illustrating a conductive wiring in accordance with some embodiments of the present invention will be discussed. The conductive wiring 91 illustrated in FIG. 4 is substantially the same as the conductive wiring 90 discussed above with respect to FIG. 3, except that the contact plug is protruded into the via hole so as to improve electrical contact reliability between the contact plug and the conductive wiring 91. As discussed above, like reference numerals refer to like elements throughout, thus details with respect to like elements of FIGS. 3 and 4 will not be repeated herein in the interest of brevity.

As illustrated in FIG. 4, the contact plug 14a is protruded from a surface of the etch-stop layer 12, and thus an upper sidewall C of the contact plug 14a is exposed in the via hole. Therefore, the conductive line 15a in the via hole makes contact with the upper sidewall C of the contact plug 14a as well as a top surface of the contact plug 14a, and thus a contact area between the contact plug 14a and the conductive line 15a is enlarged to thereby improve the electrical contact reliability between the contact plug 14a and the conductive line 15a.

The etch-stop layer 12 illustrated in FIG. 4 is discontinuous at a boundary portion of the first insulation interlayer pattern 11a and the contact plug 14a, i.e., the etch-stop layer 12 is sporadically positioned on the first insulation interlayer pattern 11a and the contact plug 14a. The etching process for forming the via hole is performed against the second insulation interlayer pattern 13a until the etch-stop layer 12 on the first insulation interlayer pattern 11a is exposed, so that the sidewall C of the contact plug 14a is exposed in the via hole. As a result, the conductive line 15a in the via hole makes contact with the upper sidewall C of the contact plug 14a as well as a top surface of the contact plug 14a, to thereby improve the electrical contact reliability between the contact plug 14a and the conductive line 15a.

Therefore, the parasitic capacitance caused by the etch-stop layer 12 may be sufficiently reduced despite the reduction of the overall thickness of the conductive line 15a, and the contact reliability between the conductive line 15a and the contact plug 14a may also be improved. As a result, operation reliability of the conductive wiring 91 may be improved by the reduction of the parasitic capacitance and the improvement of the contact reliability between the contact plug 14a and the conductive line 15a.

According to the conductive line for a semiconductor device, the etch-stop layer between first and second insulation interlayer patterns may have a reduced thickness without substantial deterioration of layer density, so that the parasitic capacitance caused by the etch-stop layer may be reduced although the overall thickness of the conductive line is decreased. Furthermore, an additional process for removing the etch-stop layer is not necessarily needed during the formation process of the via hole, thereby simplifying the formation process of the conductive wiring for a semiconductor device.

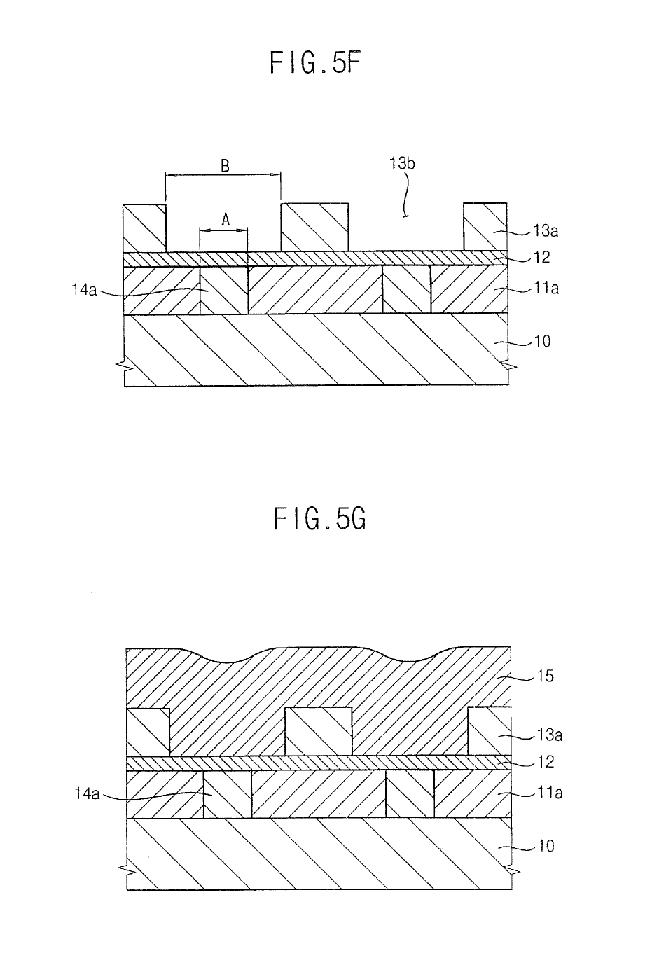

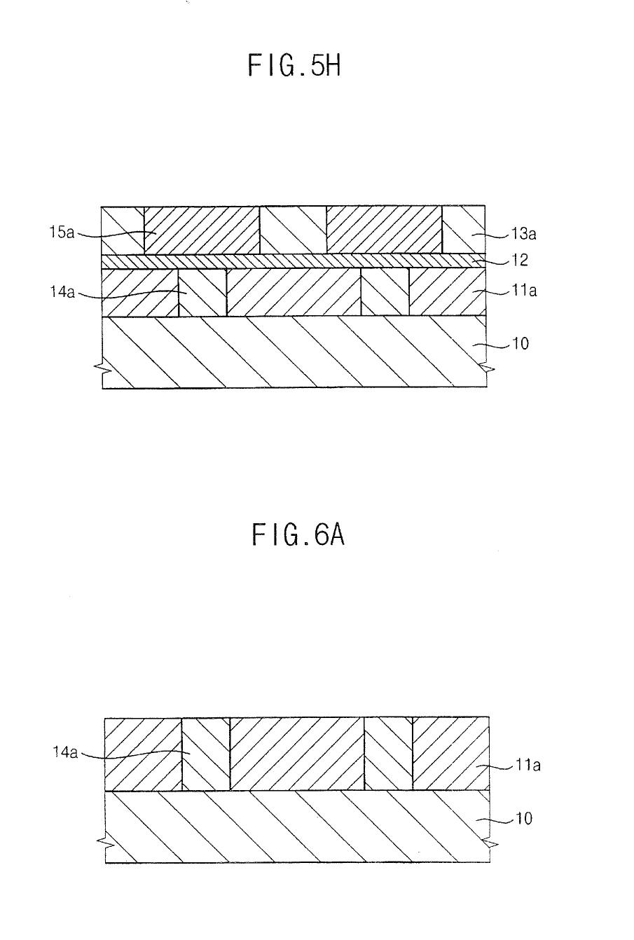

Processing steps in the fabrication of the conductive wiring for a semiconductor device will now be discussed. The conductive wiring 90 in FIG. 3 may be formed on the substrate using processing steps that will be discussed with respect to FIGS. 5A to 5H below, and the conductive wiring 91 of FIG. 4 may be formed on the substrate using processing steps that will be discussed with reference to FIGS. 6A to 6C below. Although the processing steps for forming the conductive wiring have been described as suitable examples of various embodiments of the present invention, embodiments of the present invention should not be limited to the these exemplary processing steps. Various changes and modifications can be made by one skilled in the art within the spirit and scope of the present invention.

Referring now to FIGS. 5A to 5H, cross-sections illustrating processing steps for forming the conductive wiring illustrated in FIG. 3 in accordance with some embodiments of the present invention will be discussed. As illustrated in FIGS. 3 and 5A, a first insulation interlayer 11 is formed on the substrate 10 on which various lower strictures for a semiconductor device such as a transistor and a capacitor are formed.

In some embodiments of the present invention, an operation unit structure of a flash memory device having a string selection transistor (not shown), a plurality of cell transistors, and a ground selection transistor (not shown) may be formed on the substrate 10 as the lower structures. In particular, the substrate 10 includes a cell array region in which a memory cell is formed and a peripheral region in which various electronic circuits electrically connected with the memory cell are formed. A plurality of isolation layers (not shown) is on the substrate 10 including the cell array region and the peripheral region, and an active region is defined by the isolation layer. Various conductive structures are formed in the active region and the conductive structures positioned in adjacent active regions are electrically isolated from each other by the isolation layer. For that reason, the isolation layer defining the active region may be referred to as device isolation layer hereinafter. The cell array region includes a plurality of strings, and a string selection transistor, a plurality of cell transistors and a ground selection transistor are electrically connected to each of the strings in series. A drain region of the string selection transistor is electrically connected to a bit line through a contact plug, and a source region of the ground selection transistor is electrically connected to a common source line. A peripheral transistor (not shown) is formed in the peripheral region of the substrate 10, and the peripheral transistor includes source/drain conjunction portions.

A gate structure for a DRAM device may be formed on the substrate 10 as the lower structure. The substrate 10 is divided into an active region and a field region, and the conductive gate structure is formed on the substrate of the active region. An ion implantation process may be performed on the substrate using the gate structure as an implantation mask, to thereby form source/drain regions adjacent to the gate structure. The gate structure and the source/drain regions around the gate structure complete a gate electrode of the DRAM device. An insulation layer is formed on the substrate including the gate electrode and a plurality of contact pads, which is electrically connected with the source/drain regions, are formed in the insulation layer by a self-aligned process.

An insulation layer (not shown) is formed on the substrate including the lower structures. The insulation layer electrically insulates adjacent lower structures from each other and protects the lower structures in a subsequent etching process. In some embodiments of the present invention, the insulation layer may include an oxide layer and a top surface thereof is planarized by a planarization process, such as a chemical mechanical polishing (CMP) process. As a result, the insulation layer has a flat top surface. The insulation layer may include at least one insulation interlayer.

In some embodiments of the present invention, a first insulation interlayer 11 is formed on the substrate 10 including the lower structures thereon. For example, the first insulation interlayer 11 may include TEOS, and is formed on the substrate 10 by a PECVD process or a high-density plasma chemical vapor deposition (HDPCVD) process using tetraethoxysilane (Si(OC₂H₅)₄) gas and oxygen (O₂) or ozone (O₃) gas as source gases. The first insulation interlayer 11 is formed to have a sufficient thickness that the lower structures on the substrate 10 are sufficiently protected from a subsequent etching process. For example, the insulation interlayer 11 is formed to a thickness of from about 4,000 Å to about 5,000 Å. Impurities such as boron (B) or phosphorus (P) may be further implanted onto the substrate 10 after the deposition process by an ion implantation process, to thereby reduce the dielectric constant of the first insulation interlayer 11.

Referring now to FIGS. 3 and 5B, a photoresist pattern (not shown) is formed on the first insulation interlayer 11 by a photolithography process, and the first insulation interlayer 11 is partially exposed through the photoresist pattern. The first insulation interlayer 11 is etched off by an etching process using the photoresist pattern as an etching mask, to thereby form the first insulation interlayer pattern 11a including at least one contact hole 11b. For example, the first insulation interlayer 11 may be partially etched off by a dry etching process using plasma. The photoresist pattern is removed from the first insulation interlayer pattern 11a by a strip process, and contaminants, such as polymer, in the contact hole 11b are removed from the substrate 10 by a cleaning process.

Referring now to FIGS. 3 and 5C, first conductive materials are deposited onto the substrate 10 including the first insulation interlayer pattern 11a, so that a first conductive layer 14 is formed on the substrate 10 to a sufficient thickness to fill up the contact hole 11b. The first conductive material may include polysilicon and a metal, such as tungsten (W) and aluminum (Al). In some embodiments of the present invention, the first conductive layer 14 may include a single layer, such as a polysilicon layer and a metal layer, or a multilayer in which the polysilicon layer and the metal layer are stacked on the substrate 10. The first conductive layer 14 is to be formed into the contact plug 14a in the contact hole 11b by a subsequent planarization process described hereinafter. In embodiments of the present invention where the first conductive layer 14 includes a tungsten (W) layer, a titanium (Ti) layer or a titanium nitride (TiN) layer may be further formed between the contact plug 14a and the first insulation interlayer pattern 11a and between the contact plug 14a and the substrate 10, so that electrical resistance may be decreased at a boundary surface of the contact plug 14a.

Referring now to FIGS. 3 and 5D, the contact plug 14a is formed in the contact hole 11b by the planarization process, and the etch-stop layer 12 is uniformly formed on the first insulation interlayer pattern 11a and the contact plug 14a. In particular, the first conductive layer 14 is partially removed from the substrate 10 by the planarization process, such as a CMP process, until a top surface of the first insulation interlayer pattern 11a is exposed, so that the first conductive layer 14 remains only in the contact hole 11b to thereby form the contact plug 14a in the contact hole 11b. A top surface of the first insulation interlayer pattern 11a is coplanar with a top surface of the contact plug 14a, and the top surfaces of the first insulation interlayer pattern 11a and the contact plug 14a become a flat plane. Accordingly, the contact plug 14a is formed to substantially the same thickness as the first insulation interlayer pattern 11a in a range of from about 4,000 Å to about 5,000 Å.

A thin layer is formed on the flat top surfaces of the first insulation interlayer pattern 11a and the contact plug 14a by a minute process for manipulating minute particles, such as atoms and molecules, thereby forming the etch-stop layer 12 having an etching selectivity with respect to the second insulation interlayer that is to be formed on the etching stop layer in a subsequent process.

In some embodiments of the present invention, particles such as carbon (C) atoms and nitrogen (N) atoms or molecular gases including carbon (C) and nitrogen (N) are implanted onto the flat top surfaces of the first insulation interlayer pattern 11a and the contact plug 14a by an ion implantation process. The ion implantation allows the thickness of the etch-stop layer to be controlled accurately with a high density. Accordingly, the etch-stop layer is formed to have a small thickness without substantial deterioration of the layer density, and has sufficient etch-resistance with respect to the second insulation interlayer pattern 13a despite the small thickness thereof. For example, the etch-stop layer 12 may include silicon carbide (SiC), silicon nitride (SiN), silicon oxynitride (SiON) or silicon oxycarbide (SiOC), and may be formed to a thickness of from about 50 Å to about 200 Å.

A GCIB process may be further performed on the etch-stop layer 12 after completing the ion implantation process, thereby improving the surface uniformity and the layer density of the etch-stop layer 12. In the above GCIB process, an energy state of each atom in an accelerated gas cluster approximates to an individual bonding energy of a surface of the substrate 10, so that the surface roughness of the etch-stop layer 12 is remarkably improved by the GCIB process. Accordingly, the GCIB process may remarkably improve the layer uniformity, the surface flatness and the layer density of the etch-stop layer 12.

A closed molding process, such as a surface infusion and an inter-laminar infusion may be utilized for the formation of the etch-stop layer 12 as well as the ion implantation process. In particular, the substrate 10 including the first insulation interlayer pattern 11a and the contact plug 14a is provided into a closed mold of which the inner space is formed to be vacuous. An atomic or a molecular material layer is formed on the flat top surface of the first insulation interlayer pattern 11a and the contact plug 14a, to thereby form the etch-stop layer 12 on the first insulation interlayer pattern 11a and the contact plug 14a.

The etch-stop layer 12 is formed to have a small thickness without deterioration of the layer density, and has an etching selectivity with respect to the second insulation interlayer pattern 13a. In particular, the etch-stop layer 12 including carbon (C) or nitrogen (N) has such a sufficiently small thickness that the electrical resistance at a boundary surface of the conductive line 15a and the contact plug 14a is not increased even though the etch-stop layer 12 is between the conductive line 15a and the contact plug 14a. Accordingly, when an etching process for forming the via hole in which the conductive line 15a is positioned is performed against the second insulation interlayer pattern 13a, there is no need for removing the etch-stop layer from a bottom of the via hole in a subsequent process, thereby possibly improving processing efficiency.

Referring to FIGS. 3 and 5E, a second insulation interlayer 13 is formed on the etch-stop layer 12. In some embodiments, the second insulation interlayer 13 may include oxide like the first insulation interlayer 11. For example, the second insulation interlayer 13 may exemplarily include BPSG, PSG, FSG, PE-TEOS, USG or any combination thereof. The second insulation interlayer 13 may not necessarily include the same material as the first insulation interlayer 11. However, in some embodiments of the present invention, the second insulation interlayer 13 may include PE-TEOS like the first insulation interlayer 11. In other words, the second insulation interlayer 13 is formed on the etch-stop layer 12 by a PECVD process using tetraethoxysilane (Si(OC₂H₅)₄) gas and oxygen (O₂) or ozone (O₃) gas as source gases. The second insulation interlayer 13 is formed to have a sufficient thickness for preparing for an inevitable layer loss in a subsequent etching process for formation of the via hole and in a subsequent planarization process for formation of the conductive line 15a. Impurities such as boron (B) or phosphorus (P) may be further implanted onto the second insulation interlayer 13 after the deposition process by an ion implantation process, to thereby reduce the dielectric constant of the second insulation interlayer 13.

Referring now to FIGS. 3 and 5F, a via hole 13b is formed in the second insulation interlayer 13 by a single damascene process, so that the etch-stop layer 12 above the contact plug 14a is exposed through the via hole 13b. In particular, a photoresist pattern (not shown) is formed on the second insulation interlayer 13 by a photolithography process, and the second insulation interlayer 13 is partially removed from the etch-stop layer 12 around the contact plug 14a by a dry etching process using the photoresist pattern as an etching mask, to thereby form the second insulation interlayer pattern 13a having the via hole 13b. The dry etching process is performed against the insulation interlayer 13 until a top surface of the etch-stop layer 12 is exposed, so that the etch-stop layer above the contact plug 14a is exposed through the via hole 13b. In some embodiments of the present invention, the via hole is formed to have a diameter B greater than a width A of the contact plug 14a, so that the conductive line 15a makes better contact with the contact plug 14a. The photoresist pattern is removed from the second insulation interlayer pattern 13a by a strip process, and contaminants such as polymer in the via hole 13b are removed from the inside of the via hole 13b by a cleaning process.

Referring now to FIGS. 3 and 5G, second conducive materials are deposited onto the substrate 10 including the second insulation interlayer pattern 13a, so that a second conductive layer 15 is formed on the substrate 10 including the second insulation interlayer pattern 13a to a sufficient thickness to fill up the via hole 13b. In some embodiments, the second material includes a superior conductive metal, such as copper (Cu), tungsten (W), aluminum (Al) and any combination thereof. In some embodiments of the present invention, copper (Cu) is deposited onto the substrate 10 including the second insulation interlayer pattern, so that a copper layer is formed on the substrate 10 including the second insulation interlayer pattern 13a as the second conductive layer 15.

Referring to FIGS. 3 and 5H, the conductive line 15a is formed in the via hole 13b by a planarization process. In particular, the second conductive layer 15 is partially removed from the substrate 10 by a planarization process, such as a CMP process, until at least a portion of a top surface of the second insulation interlayer pattern 13a is exposed, so that the second conductive layer 15 remains only in the via hole 13b, to thereby form the conductive line 15a in the via hole 13b. As a result of the CMP process, a top surface of the conductive line 15a is coplanar with the top surface of the second insulation interlayer pattern 13a.

Accordingly, the conductive line 15a has substantially the same thickness as the second insulation interlayer pattern 13a in a range of from about 400 Å to about 700 Å.

Referring now to FIGS. 6A to 6C, cross-sections illustrating processing steps in the fabrication of the conductive wiring illustrated in FIG. 4 will be discussed. The processing steps for forming the conductive wiring 91 in FIG. 4 are substantially the same as those for forming the conductive wiring 90 in FIG. 3 discussed above with respect to FIGS. 5A to 5H, except for the processing step for forming the first insulation interlayer pattern and the processing step for forming the etch-stop layer. As discussed above, like reference numerals refer to like elements throughout, thus details with respect to like processing steps of the conductive wiring of FIGS. 3 and 4 will not be repeated herein in the interest of brevity.

A first conductive layer 14 is formed on a substrate 10 including a first insulation interlayer pattern 11a in substantially the same process as discussed above with respect to FIGS. 5A and 5C. Referring now to FIGS. 4 and 6A, the first conductive layer 14 is partially removed from the substrate 10 to thereby form a contact plug 14a on the substrate 10 to a thickness to fill up the contact hole 11b.

A first planarization process, such as a CMP process, is performed on the first conductive layer 14 until the first insulation interlayer pattern 11a is exposed, so that the first conductive layer 14 remains only in the contact hole 11b. In particular, slurry for the first planarization process is controlled to have such composition that the first conductive layer 14 and the first insulation interlayer pattern 11a are removed from the substrate 10 at a ratio of about 1:1. Therefore, the first conductive layer 14 and a top portion of the first insulation interlayer pattern 11a are partially removed from the substrate 10, so that the first conductive layer remains only in the contact hole 11b to thereby form the contact plug 14a in the contact hole 11b. When a barrier metal layer (not shown) may be further formed on a top surface of the first insulation interlayer pattern 11a and on a sidewall and a bottom of the contact hole 11b so as to reduce the likelihood that metals in the contact plug 14a will diffuse into the first insulation interlayer pattern 11a and improve contact resistance between the contact plug 14a and the substrate 10, the slurry for the first planarization process may be controlled to have such composition that the first conductive layer 14, the barrier metal layer and the first insulation interlayer pattern 11a are removed from the substrate 10 at a ratio of about 1:1:1.

Referring now to FIGS. 4 and 6B, a second planarization process may be performed on the substrate 10 including the contact plug 14a and the first insulation interlayer pattern 11a, to thereby form a reduced pattern 11c on the substrate 10. An upper portion of the first insulation interlayer pattern 11a is removed from the substrate 10 by the second planarization process, so that an upper sidewall of the contact plug 14a is exposed to surroundings. Slurry for the second planarization process is controlled to have such composition that only the first insulation interlayer pattern 11a is removed from the substrate 10 without any removal of the contact plug 14a. Therefore, the size of the exposed sidewall C of the contact plug 14a is determined in accordance with processing time and velocity of the second planarization process.

Referring now to FIGS. 4 and 6C, minute particles such as atoms and molecules are implanted onto the substrate 10 including the contact plug 14a and the reduced pattern 11c, to thereby form an etch-stop layer 12 on the contact plug 14a and the reduced pattern 11c. The processing step for forming the etch-stop layer 12 using the minute particles is substantially the same processing step as described with reference to FIG. 5D, so that any details with respect to the formation of the etch-stop layer will not be repeated herein.

Subsequent processing steps are performed on the etch-stop layer 12 in substantially the same method as discussed above with respect to FIGS. 5E to 5H, to thereby form the conductive wiring 91 on the substrate 10 as illustrated in FIG. 4. Some embodiments of the present invention, allow the conductive wiring 91 to have an enlarged contact area between the conductive line 15a and the contact plug 14a as large as the exposed sidewall C of the contact plug 14a, thereby improving electrical reliability of the conductive wiring 91.

According to some embodiments of the present invention, the etch-stop layer 12 between the first and the second insulation interlayer patterns 11a and 13a may be formed to have a thickness as small as possible, so that the parasitic capacitance caused by the etch-stop layer 12 may be sufficiently reduced although the conductive line on the contact plug may have a small thickness. Furthermore, there is no need for the etch-stop layer to be removed from the contact plug in the contact hole after completing the process for forming the via hole, thereby improving processing efficiency for a damascene process for forming the conductive line.

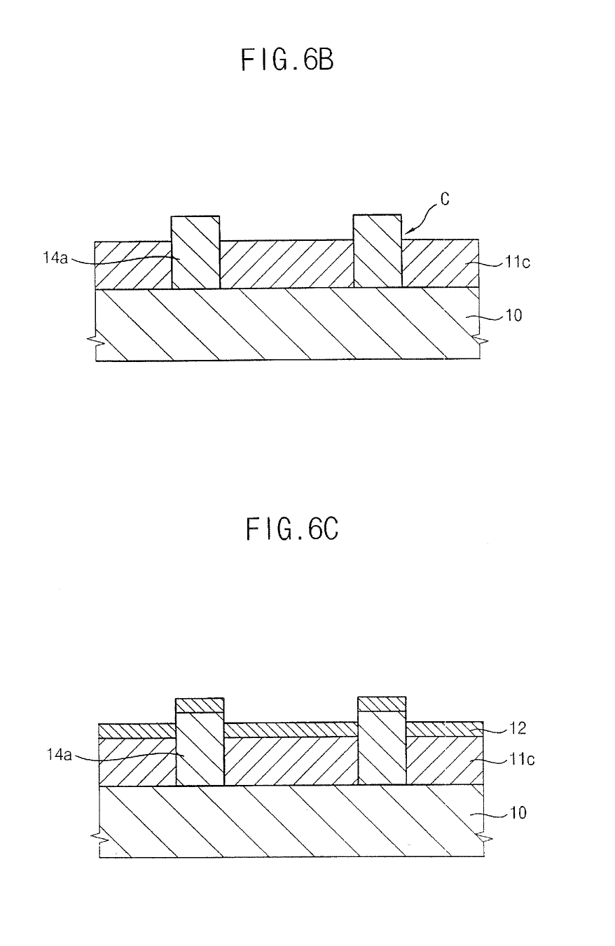

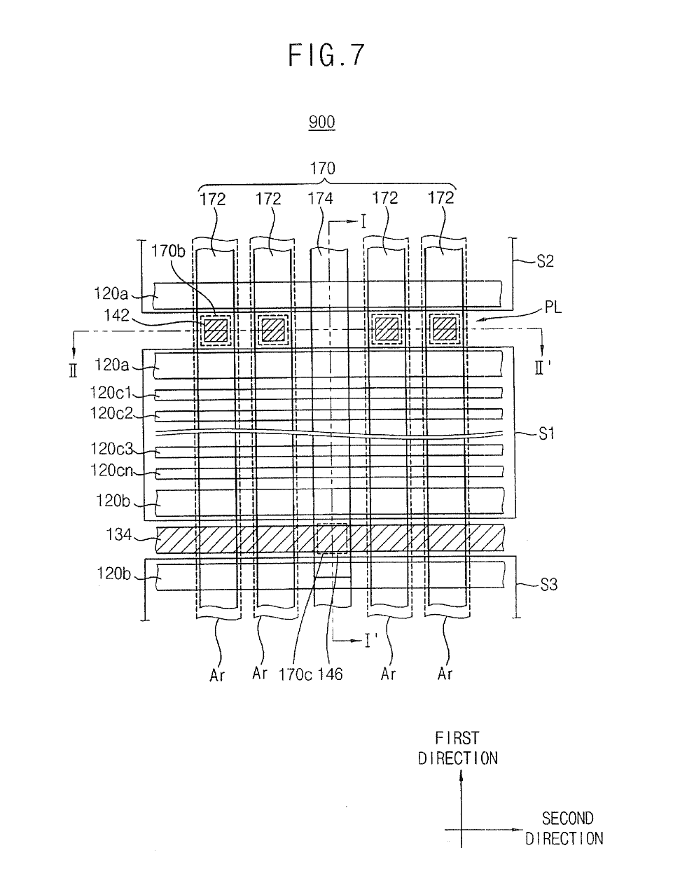

FIG. 7 is a plan view illustrating a flash memory device in accordance with some embodiments of the present invention, FIG. 5A is a cross-section taken along a line I-I′ of the flash memory device illustrated in FIG. 7, and FIG. 8B is a cross-section taken along a line II-II′ of the flash memory device illustrated in FIG. 7. Referring now to FIGS. 7, 8A and 8B, the flash memory device 900 includes a semiconductor device 100 including an insulation layer 103 by which the substrate 100 is divided into an active region Ar and a field region. That is, the active region Ar is defined by the insulation layer 103, and various conductive structures are positioned on the active region. The conductive structures on adjacent active regions are electrically isolated from each other by the insulation layer, and the conductive structure on each active region is individually operated as a unit operation device of the flash memory device regardless of the adjacent conductive structures. Thus, the insulation layer 103 is referred to as a device isolation layer. In some embodiments of the present invention, the active region Ar is formed into a plurality of lines extending a first direction of the substrate 100, and each of the lines is separated from one another by the device isolation layer 103.

First, second and third gate patterns 120a, 120b and 120c extend on the substrate 100 in a second direction perpendicular to the first direction, so that the first, second and third gate patterns 120a, 120b and 120c cross the active region Ar and the field region filled up with the device isolation layer 103. In some embodiments of the present invention, the first gate pattern 120a functions as a string selection line (SSL) in the flash memory device 900, and the second gate pattern 120b functions as a ground selection line (GSL) in the flash memory device 900. The third gate pattern 120c includes a group of patterns between the first and second gate patterns 120a and 120b, and functions as word lines (WLs) in the flash memory device 900.

The first, second and third gate patterns 120a, 120b and 120c includes a string selection transistor (SST), a ground selection transistor (GST) and a cell transistor (CT) at an intersection point of each gate pattern and the active region Ar, respectively. Each of the SST, GST and CT includes a multilayer in which a gate oxide layer (not shown), a floating gate (105), a gate dielectric layer (107) and a control gate (109) are sequentially stacked on the substrate 100. In some embodiments of the present invention, the floating gate 105 may include a polysilicon layer doped with impurities, and the gate dielectric layer 107 may include a multilayer having an oxide layer, a nitride layer and an oxide layer (ONO layer) or a single layer such as a tantalum oxide (Ta₂O₅) layer. The control gate 109 may include a single layer, such a polysilicon layer, or a multilayer having a polysilicon layer and a metal silicide layer. For example, the metal silicide layer may include a tungsten silicide (WSiₓ) layer, a cobalt silicide (CoSiₓ) layer, and a nickel silicide (NiSiₓ) layer. A capping layer 111 may be further positioned on the gate patterns 120a, 120b and 120c, and a spacer 125 may be further positioned on a sidewall of each transistor in each of the gate patterns. For example, the capping layer 111 may include a silicon nitride layer, and the spacer 125 may include a silicon nitride layer, a silicon oxide layer and a multilayer including the silicon nitride layer and the silicon oxide layer.

Each of the SST, GST and a plurality of CTs arranged in the same active region Ar of the substrate 100 in the first direction has heavily-doped source/drain regions (not shown) at portions of the active region Ar exposed through the first, second and third gate patterns 12a, 120b and 120c. In particular, a memory cell array may include a plurality of intersections of the active regions Ar extending in the first direction and the WLs 120c spaced apart from each other in the second direction, and the SSL and GSL are positioned apart from a first WL 120c₁ and from an nth WL 120cₙ, respectively. The memory cell array, the SSL and the GSL may constitute a ‘string’ that is an operation unit of the flash memory device 900. A pair of the adjacent cell transistors in the string commonly shares the source/drain regions in the same active region Ar of the substrate 100 extending in the first direction, so that the cell transistors are electrically connected with each other in series along the first direction.

An insulation layer 130 is formed on the substrate 100 including the first, second and third gate patterns 120a, 120b and 120c, so that the first, second and third gate patterns 120a, 120b and 120c are electrically insulated from one another and upper structures above the gate patterns 12a, 120b and 120c are electrically insulated from the gate patterns 12a, 120b and 120c. In some embodiments of the present invention, the insulation layer 130 may include a protection layer 130a and a planarization layer 130b on the protection layer 130a. The protection layer 130a is formed on the substrate 100 along profiles of the first, second and third gate patterns 120a, 120b and 120c, so that the first, second and third gate patterns 120a, 120b and 120c are prevented from being etched off in a subsequent process, and the planarization layer 130b fills up spaces between the first, second and third gate patterns 120a, 120b and 120c and a top surface thereof is flat due to a subsequent planarization process. In some embodiments of the present invention, the protection layer 130a may include a high-density plasma oxide layer or an undoped silicate glass layer having high gap-fill characteristics, so that the spaces between the first, second and third gate patterns 120a, 120b and 120c are filled with the protection layer 130a. The planarization layer 130b is formed on the protection layer 130a to a sufficient thickness to fill up the spaces between the first, second and third gate patterns 120a, 120b and 120c, and a top surface thereof is flat due to a planarization process such as a CMP process. For example, the planarization layer 130b may include TEOS.

The insulation layer 130 may include a first contact hole 132 through which the active region Ar and the device isolation layer 103 between the GSLs adjacent to each other in the first direction are exposed, and a second contact hole 136 through which the active region Ar between the SSTs adjacent to each other in the second direction are exposed. A plurality of the first contact holes 132 is arranged along the GSL line and each of the first contact holes 132 is filled up with conductive materials such as polysilicon to thereby form a common source line (CSL, 134) in the first contact hole 132 in parallel with the GSL. Therefore, the active regions Ar and the device isolation layers exposed through the first contact holes 132 are commonly connected with the CSL 134. In some embodiments of the present invention, a top surface of the CSL 34 is coplanar with a top surface of the insulation layer 130.

A first insulation interlayer pattern 140a is formed on the insulation layer 130 and the CSL 134, to thereby electrically insulate the contact plug 144 from upper structures above the contact plug 144. The first insulation interlayer pattern 140a includes a first via hole 142 connected to the second contact hole 136 and a second via hole 146 in which a cell metal wiring 174 is positioned and makes electrical contact with the CSL 134. In some embodiments of the present invention, the first insulation interlayer pattern 140a has a thickness of from about 4,000 Å to about 5,000 Å. Conductive materials are positioned in the second contact hole 136 and the first via hole 142, to thereby form the contact plug 144 in the second contact hole 136 and the first via hole 142. Therefore, the contact plug 144 makes electrical contact with each active region Ar between adjacent SSTs.

In some embodiments of the present invention, the contact plug 144 includes a single layer such as a polysilicon layer and a metal layer, for example, a tungsten (W) layer and an aluminum (Al) layer, or a multilayer in which the metal layer and the polysilicon layer are stacked. In some embodiments of the present invention, the contact plug 144 includes tungsten (W) having good conductivity. When the contact plug 144 and the CSL 134 includes tungsten (W), a titanium (Ti) layer or a titanium nitride (TiN) layer may be further positioned around the contact plug 144 and the CSL 134, so that the contact plug 144 and the CSL 134 are enclosed by the titanium (Ti) layer or the titanium nitride (TiN) layer. Therefore, impurity diffusion into the insulation layer 130 and the insulation interlayer pattern 140a is prevented and electrical resistance is reduced at a boundary surface between the substrate 100 and the contact plug 144 and between the substrate 100 and the CSL 134. A top surface of the contact plug 14 is coplanar with a top surface of the first insulation interlayer pattern 140a.

A plurality of the contact plugs 144 is positioned adjacent to each of the SSTs in each active region Ar extending along the first direction, to thereby form a contact plug line (PL) extending along the second direction in parallel with the SSL. A first string S1 including the SSL 120a, the GSL 120b and a plurality of WLs 120c between the SSL 120a and the GSL 120b is symmetrical to a second string S2 adjacent to the first string S1 with respect to the contact plug line (PL), so that the second string S2 is a mirror image of the first string S1 with respect to the contact plug line (PL). In other words, a contact plug 144 is positioned between the SSTs adjacent to each other in every active region Ar of the substrate 100, and thus the SSL adjacent to each other commonly shares the same contact plug 144 in the same active region Ar of the substrate 100.

The CSL 134 is arranged along the GSL adjacent thereto. A third string S3 is symmetrical to the first string S1 with respect to the CSL 134, so that the third string S3 is also a mirror image to the first string S1 with respect to the CSL 134. Therefore, the GSTs in the GSL also commonly share the CSL 134.

As a result, the contact plug 144 is commonly connected with drain electrodes of the SSTs of the first and second strings S1 and S2, and the CSL 134 is commonly connected with source electrodes of the GSTs of the first and third strings S1 and S3.

An etch-stop layer 150 is positioned on the flat top surfaces of the contact plug 144 and the first insulation interlayer pattern 140a. The etch-stop layer terminates an etching process against a second insulation interlayer 160 for forming a damascene pattern.

Therefore, the etch-stop layer 150 may include a material having an etching selectivity with respect to the second insulation interlayer 160. For example, the etch-stop layer 150 may include silicon carbide (SiC), silicon nitride (SiN), silicon oxynitride (SiON) and silicon oxycarbide (SiOC). These can be used alone in combinations thereof. In some embodiments of the present invention, the etch-stop layer 150 is formed on the flat top surfaces of the first insulation interlayer 140 and the contact plug 144 to a thickness of from about 50 Å to about 200 Å by an ion implantation process.

The ion implantation process may allow the etch-stop layer 150 to be formed atom by atom or molecule by molecule, so that the etch-stop layer 150 may have a sufficiently small thickness without deterioration of a layer density. Accordingly, the parasitic capacitance caused by the etch-stop layer 150 may be prevented from increasing although the thickness of the bit lines 172 and cell metal lines 174 decrease. Furthermore, etch-resistance of the etch-stop layer 150 may be improved by the ion implantation process despite the thickness reduction of the etch-stop layer 150. The etch-stop layer 150 in FIGS. 8A and 8B has substantially the same structure and composition as the etch-stop layer 12 in FIG. 3, and thus any further detailed descriptions on the etch-stop layer 150 will not be repeated herein.

A second insulation interlayer pattern 160a is formed on the etch-stop layer 150 including a first trench 162 through which the etch-stop layer 150 on the contact plug 144 is exposed and a second trench 164 through which the etch-stop layer 150 above the device isolation layer 103 is exposed.

In some embodiments of the present invention, the second insulation interlayer pattern 160a may include an oxide such as BPSG, PSG, FSG, PE-TEOS, USG or any combination thereof. The second insulation interlayer pattern 160a may not necessarily include the same material as the first insulation interlayer pattern 140a. However, in some embodiments of the present invention, the second insulation interlayer pattern 160a may include PE-TEOS like the first insulation interlayer pattern 140a.

A bit line 172 including a conductive metal is positioned in the first trench 162, and is electrically connected to the contact plug 144. A cell metal wiring 174 including the same conductive metal as the bit line 172 is positioned in the second trench 164, and is electrically connected to the CSL 134. In some embodiments of the present invention, the bit line 172 and the cell metal wiring 174 are formed in substantially the same process using the same material.

The bit line 172 has a width larger than a diameter of the first via hole 142 and extends in the first direction above the active region Ar of the substrate 100, and the cell metal wiring 174 has a width larger than a diameter of the second via hole 146 and extends in the first direction above the device isolation layer 103 in the substrate 100. Therefore, the bit line 172 is electrically connected to the contact plug 144 exposed through the first via hole 142, and is electrically insulated from a residual portion of the active region Ar including the first via hole 142 except a portion above the contact plug 144 by the first insulation layer 130. Furthermore, contact plugs adjacent to each other in adjacent active regions are also electrically insulated from each other by the second insulation interlayer pattern 160a. The cell metal wiring 174 in the second via hole 146 is electrically connected to the CSL 134 exposed through the insulation layer 130.

According to some embodiments of the flash memory device, the etch-stop layer 150 between the first and second insulation interlayer patterns 140a and 160a has a remarkably small thickness, so that the parasitic capacitance caused by high dielectric constant of the etch-stop layer 150 may be sufficiently reduced despite the thickness reduction of the bit line. Furthermore, the etch-stop layer 150 has a high layer density by using an ion implantation process, and thus may have a sufficiently strong etch-resistance during an etching process for forming other trenches in a subsequent damascene process.

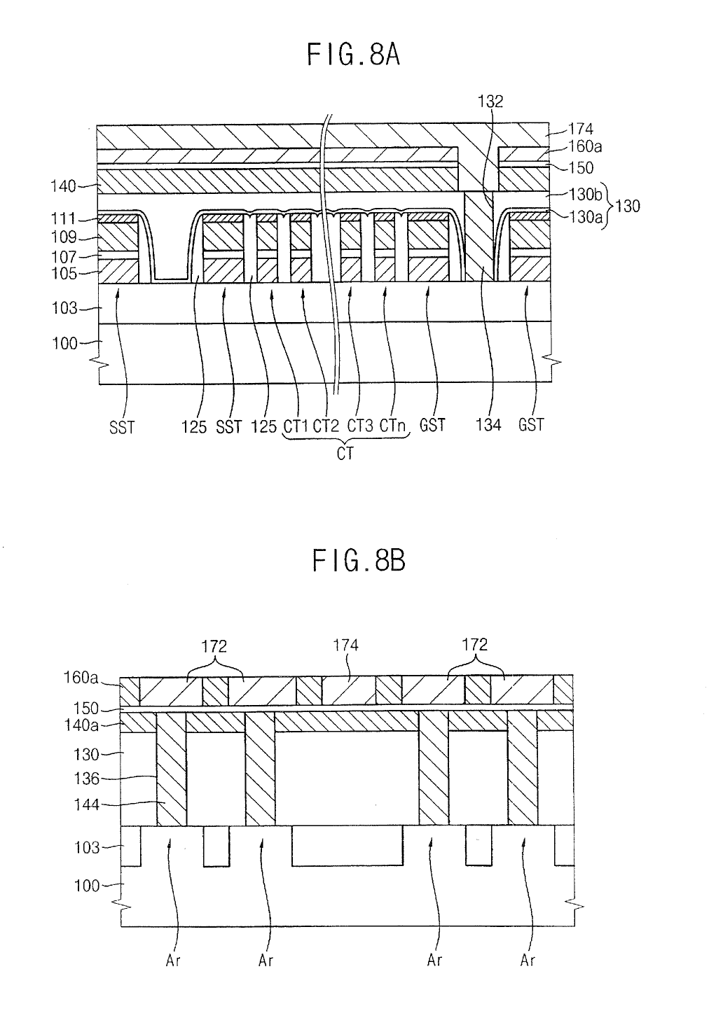

The flash memory device 900 is manufactured through the following processing steps in accordance with some embodiments of the present invention. Hereinafter, processing steps in the fabrication of the flash memory device illustrated in FIGS. 7, 8A and 8B will be discussed with respect to FIGS. 9A to 12B. It will be understood that some embodiments disclose a suitable example of the present invention, but embodiments of the present invention are not limited to this configuration. Furthermore, the flash memory device described as an example embodiment of a semiconductor device using the conductive wire according to some embodiments of the present invention as a bit line, so that any other semiconductor devices known to one of ordinary skill in the art may also uses the conductive wore illustrated in FIG. 3. For example, the conductive line in FIG. 3 may also be utilized as a bit line for a DRAM device.

FIGS. 9A to 13B are cross-sections illustrating processing steps in the fabrication of flash memory devices including the conductive line illustrated in FIG. 3 according to some embodiments of the present invention. FIGS. 9A, 10A, 11A, 12A and 13A are cross-sections taken along a line I-I′ of FIG. 7, and FIGS. 9B, 10B, 11B, 12B and 13B are cross-sections taken along a line II-II′ of FIG. 7. Referring first to FIGS. 7, 9A and 9B, there is provided the semiconductor substrate 100 including a cell array region. The device isolation layer 103 is formed on the substrate 100 and an active region Ar in which various conductive structures are positioned is defined on the substrate 100. In some embodiments of the present invention, the device isolation layer 103 is formed on the substrate 100 by a shallow trench isolation (STI) process, so that the active region Ar defined by the device isolation layer 103 is formed into a line shape extending the first direction on the substrate 100.

The first, second and third gate patterns 120a, 120b and 120c are formed on the active region Ar of the substrate 100. The first gate pattern 120a functions as an SSL of the flash memory device 900. The second gate pattern 120b functions as a GSL of the flash memory device 900. A plurality of the third gate patterns 120c are positioned between the first and second gate patterns 120a and 120b, and functions as WLs of the flash memory device 900.

The active region Ar adjacent to the first gate pattern 120a is formed into an impurity region to thereby form a string selection transistor (SST) at an intersection of the SSL and the active region Ar. The active region Ar adjacent to the second gate pattern 120b is also formed into an impurity region, to thereby form a ground selection transistor (GST) at an intersection of the GSL and the active region Ar. The active region Ar adjacent to the third gate pattern 120c is formed into an impurity region to thereby form a CT at an intersection of the WL and the active region Ar. Each of the SST, GST and CTs includes a multilayer structure in which a gate oxide layer (not shown), a floating gate 105, a gate dielectric layer 107 and a control gate 109 are stacked on the substrate 100. A capping layer 111 may be further formed on the gate patterns, and a spacer 125 may be further formed on a sidewall of each of the SST, GST and CTs. A first ion implantation process is formed onto the active region Ar of the substrate 100 using the gate patterns 120a, 120b and 120c as an ion implantation process, to thereby form lightly doped impurity regions at surface portions of the active region Ar adjacent to the gate patterns 120a, 120b and 120c, respectively. A second ion implantation process is formed onto the active region Ar of the substrate 100 using the gate patterns 120a, 120b and 120c and the spacers 115 as an ion implantation process, to thereby form heavily doped impurity regions at surface portions of the active region Ar adjacent to the gate patterns 120a, 120b and 120c, respectively.

The insulation layer 130 is formed on the substrate 100 including the gate patterns 120a, 120b and 120c. In some embodiments of the present invention, materials having high gap-fill characteristics such as plasma oxides or undoped silicate glass are deposited onto the substrate 100 including the first, second and third gate patterns 120a, 120b and 120c, to thereby form the protection layer 130a on the substrate 100 along the profiles of the first, second and third gate patterns 120a, 120b and 120c. Thereafter, TEOS is deposited onto protection layer 130a by a PECVD process, to thereby form a PE-TEOS layer on the protection layer 130a to a sufficient thickness to fill up the space between the gate patterns 120a, 120b and 120c. The PE-TEOS layer is removed from the protection layer 130a by a planarization process such as a CMP process, to thereby form the planarization layer 130b having a flat top surface. As a result, the gate patterns 120a, 120b and 120c are covered with the insulation layer 130 of which the top surface is flat and are electrically insulated from one another by the insulation layer 130.

A first etching process is performed against the insulation layer 130 using a first mask as an etching mask, thereby forming the first contact hole 132 exposing the active region Ar between the adjacent GSTs and the device isolation layer 103 between the active regions Ar of the substrate 100. Impurities are implanted onto the substrate 100 exposed through the first contact hole 132, thereby forming an implantation area (not shown) on the substrate 100. As a result, a continuous conductive line is formed on cell source regions and the ion implantation areas between the cell source regions in parallel with the GSL. A first conductive layer is formed on the first insulation layer 130 to a sufficient thickness to fill up the first contact hole 132. A planarization process, such as a CMP process, and an etching process against a whole surface of the first conductive layer is performed on the first conductive layer until a top surface of the first insulation layer 130 is exposed, to thereby form the common source line (CSL) 134 in the first contact hole 132. As a result, a top surface of the CSL 134 is coplanar with the top surface of the insulation layer 130. In some embodiments of the present invention, the first conductive layer may include polysilicon doped with impurities.

Referring now to FIGS. 7, 10A and 110B, a first insulation interlayer 140 is formed on the insulation layer 130 through which the CSL 134 is formed. The first insulation interlayer may electrically insulate the CSL 134 from contact plugs for bit lines that are formed in a subsequent process.

In some embodiments of the present invention, the first insulation interlayer 140 may include BPSG, PSG, FSG, PE-TEOS, USG or any combination thereof. In some embodiments of the present invention, the first insulation interlayer 140 may include PE-TEOS, and is formed on the insulation layer 130 by a PECVD process or a high-density plasma CVD (HDPCVD) process using tetraethoxysilane (Si(OC₂H₅)₄) gas and oxygen (O₂) or ozone (O₃) gas as source gases. Thereafter, impurities such as boron (B) or phosphorus (P) may be further implanted onto the first insulation interlayer 140 after the deposition process by an ion implantation process, to thereby reduce the dielectric constant of the first insulation interlayer 140.

A second etching process is performed against the first insulation interlayer 140 and the insulation layer 130 under the first insulation interlayer 140 using a second mask as an etching mask, thereby forming the first via hole 142 through which the active regions Ar are exposed between adjacent SSTs and the second contact hole 136 that is connected to the first via hole 142. In some embodiments of the present invention, the first insulation interlayer 140 is formed to such a sufficient thickness for preparing for an inevitable layer loss in a subsequent etching process for forming the contact plug. Hereinafter, the first insulation interlayer 140 including the first via hole 142 is referred to as first insulation interlayer pattern and is designated as a reference numeral 140a.

A second conductive layer (not shown) is formed on the first insulation interlayer pattern 140a to a sufficient thickness to fill up the first via hole 142 and the second contact hole 136. The second conductive layer is partially removed from the first insulation interlayer pattern 140a until a top surface of the first insulation interlayer pattern 140a is exposed by a planarization process such as a CMP process and an etch-back process. Accordingly, the second conductive layer remains only in the second contact hole 136 and the first via hole 142, thereby forming the contact plug 144 in the second contact hole 136 and the first via hole 142. A top surface of the contact plug 144 is coplanar with the top surface of the first insulation interlayer pattern 140a, and the etching process and the planarization process are controlled under the conditions that the first insulation interlayer pattern 140a is formed to a thickness of from about 4,000 Å to about 5,000 Å.

The second conductive layer may include a metal such as tungsten (W) and aluminum (Al). In some embodiments of the present invention, the second conductive layer may include a single layer such as a metal layer having tungsten (W) or aluminum (Al) and a polysilicon layer, or may include a multilayer in which the metal layer and the polysilicon layer are stacked. In embodiments of the present invention where the contact plug 144 includes a tungsten (W) layer, a barrier layer (not shown) including titanium (Ti) or titanium nitride (TiN) may be further between the contact plug 144 and the first insulation interlayer pattern 140a and between the contact plug 144 and the substrate 100, so that electrical resistance may be decreased at a boundary surface of the contact plug 144.

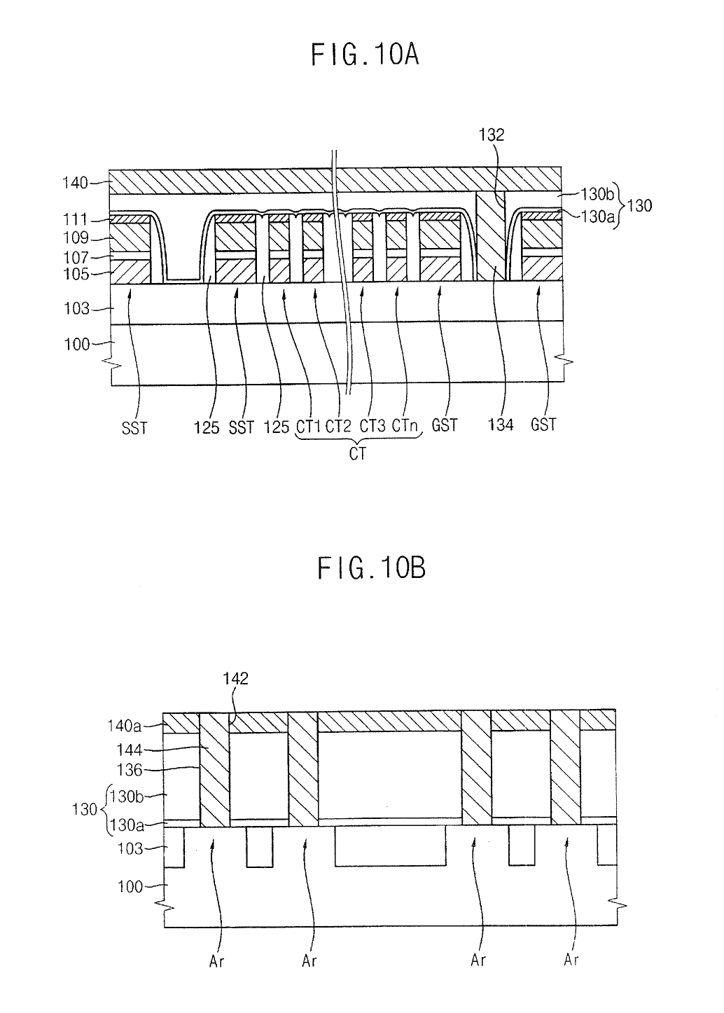

Referring now to FIGS. 7, 11A and 11B, a layer formation process is performed on the flat top surfaces of the first insulation interlayer pattern 140a and the contact plug 144 atom by atom or molecule by molecule, thereby forming the etch-stop layer 150 having an etching selectivity with respect to a second insulation interlayer 160 that is to be formed on the etch-stop layer 150 in a subsequent process.

In particular, particles including carbon (C) atoms or nitrogen (N) atoms or molecular gases including carbon (C) atoms and nitrogen (N) atoms are implanted onto the top flat surfaces of the contact plug 144 and the first insulation interlayer pattern 140a. The ion implantation allows the thickness of the etch-stop layer to be controlled accurately with a high density as compared with a deposition process. Accordingly, the etch-stop layer 150 is formed to have a small thickness without deterioration of the layer density, and has sufficient etch-resistance with respect to the second insulation interlayer 160 despite the small thickness thereof.

For example, the etch-stop layer 150 may include silicon carbide (SiC), silicon nitride (SiN), silicon oxynitride (SiON) or silicon oxycarbide (SiOC), and may be formed to a thickness of from about 50 Å to about 200 Å. These can be used alone in combinations thereof.

Accordingly, the etch-stop layer 150 including carbon (C) or nitrogen (N) may be formed to such a thin thickness that contact resistance may hardly be increased at a boundary surface between the bit line and the contact plug and between the cell metal wiring and the common source line 134. Accordingly, additional etching processes for forming the etch-stop layer may be omitted after completing the etching process against the second insulation interlayer, to thereby simplify manufacturing process for a semiconductor device.

The processing step for forming the etch-stop layer 150 and the composition of the etch-stop layer 150 are substantially the same process step and composition as the conductive line described in detail with reference to FIGS. 4 and 5F, and thus any further descriptions on the process step and composition of the etch-stop layer 150 will not be repeated herein.

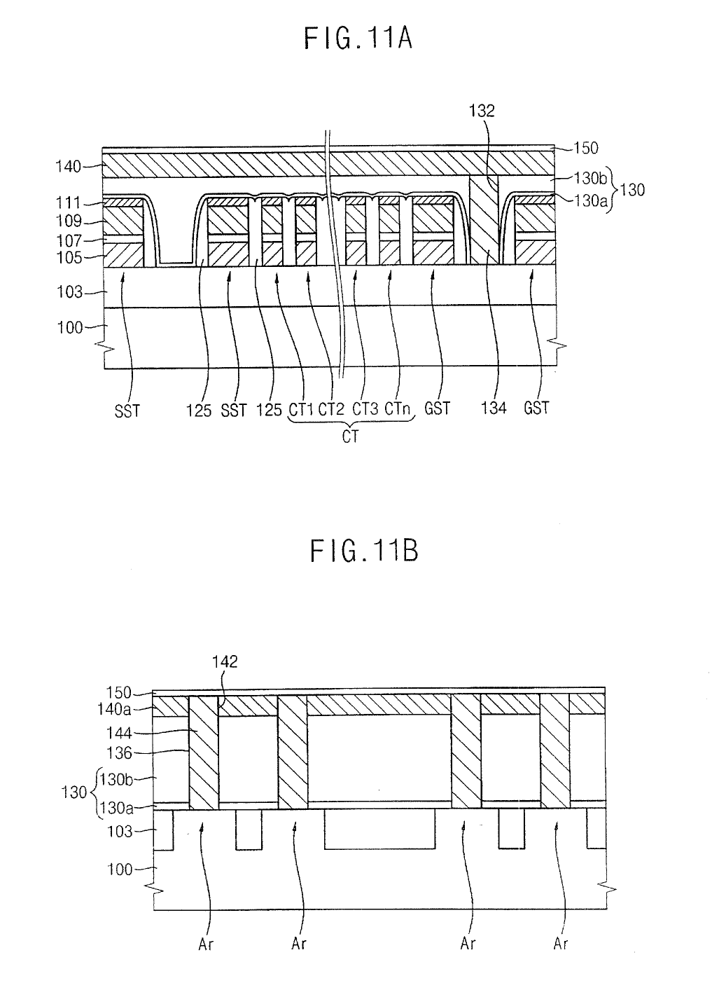

Referring to FIGS. 7, 12A and 12B, the second insulation interlayer (not shown) is formed on the etch-stop layer 150, and is patterned into the second insulation interlayer pattern 160a including a first trench 162 through which the etch-stop layer 150 above the contact plug 134 is exposed and a second trench 164 through which the CSL 134 is exposed.

In some embodiments of the present invention, the second insulation interlayer may include oxide like the first insulation interlayer 140. For example, the second insulation interlayer may exemplarily include BPSG, PSG, FSG, PE-TEOS, USG or any combination thereof. The second insulation interlayer may not necessarily include the same material as the first insulation interlayer 140. However, in some embodiments of the present invention, the second insulation interlayer may include PE-TEOS like the first insulation interlayer 140. In other words, the second insulation interlayer is formed on the etch-stop layer 150 by a PECVD process using tetraethoxysilane (Si(OC₂H₅)₄) gas and oxygen (O₂) or ozone (O₃) gas as source gases. The second insulation interlayer 13 is formed to a sufficient thickness for preparing for an inevitable layer loss in a subsequent etching process for formation of the first and second trenches 162 and 164 and in a subsequent planarization process for formation of the bit line and the cell metal wiring.

The second insulation interlayer is partially removed from the etch-stop layer 150, thereby forming the first trench 162 through which the etch-stop layer 150 above the contact plug 134 is exposed, and the second insulation interlayer and the etch-stop layer 150 under the second insulation interlayer are sequentially removed from the substrate 100, thereby forming the second trench 164 through which the CSL 134 on the device isolation layer 103 is exposed. Hereinafter, the second insulation interlayer including the first and second trenches 162 and 164 are referred to as second insulation interlayer pattern and is designated as a reference numeral 160a.

In some embodiments of the present invention, the first and second trenches 162 and 164 are formed in the second insulation interlayer by a single damascene process. In particular, a third etching process is performed on the second insulation interlayer using a third mask (not shown), and thus the second insulation interlayer is partially removed from the etch-stop layer 150 in such a manner that the contact plug 144 and the CSL 134 are exposed. The etch-stop layer on the contact plug 144 is not necessarily removed in the single damascene process. However, the etch-stop layer 150 on the CSL 134 is removed simultaneously when the first insulation interlayer pattern 140a is removed from the substrate 100.

The first trench 162 is formed to have a width greater than the diameter of the first via hole 142, and the second trench 164 is formed to have a width greater than the diameter of the second via hole 146. Therefore, the bit line and the cell metal wiring have improved contact reliability with respect to the contact plug and the CSL, respectively.

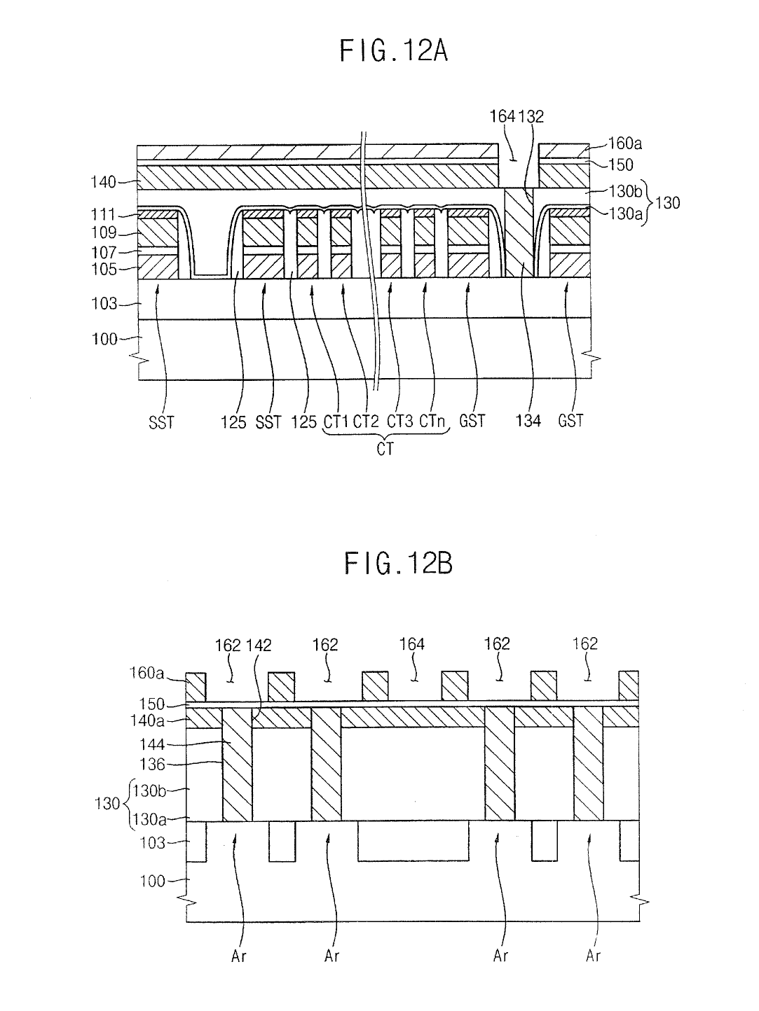

Referring now to FIGS. 7, 13A and 13B, the bit line 172 and the cell metal wiring 174 are formed in the first and second trenches 162 and 164. Conductive materials are deposited onto the second insulation interlayer pattern 160a including the first and second trenches 162 and 164, to thereby form a third conductive layer (not shown) on the second insulation interlayer pattern 160a to a sufficient thickness to fill up the first and second trenches 162 and 164. In some embodiments of the present invention, the third conductive layer may include a material having good conductivity such as copper (Cu), tungsten (W) and aluminum (Al). These can be used alone in combinations thereof. In some embodiments of the present invention, copper (Cu) is deposited onto the second insulation interlayer pattern 160a, thereby forming a copper layer on the second insulation interlayer pattern 160a to a sufficient thickness to fill up the first and second trenches 162 and 164 as the third conductive layer.

The third conductive layer is partially removed from the second insulation interlayer pattern 160a by a planarization process such as a CMP process and an etch-back process, so that the third conductive layer remains only in the first and second trenches 162 and 164 to thereby form the conductive line 170 in the first and second trenches 162 and 164. The conductive line 170 includes the bit line 172 that is electrically connected to the contact plug 144 and extends along the first direction above the active region Ar and the cell metal wiring that is electrically connected to the CSL 134 and extends along the first direction above the device isolation layer. The contact plug 144 and the CSL 134 are electrically insulated from each other by the first insulation interlayer pattern 140a, so that the bit line is also electrically insulated from the CSL 134.

As a result of the planarization process, a top surface of the conductive line 170 is coplanar with the top surface of the second insulation interlayer pattern 160a, so that the conductive line 170 and the second insulation interlayer pattern 160a have substantially the same thickness in a range of from about 400 Å to about 700 Å.

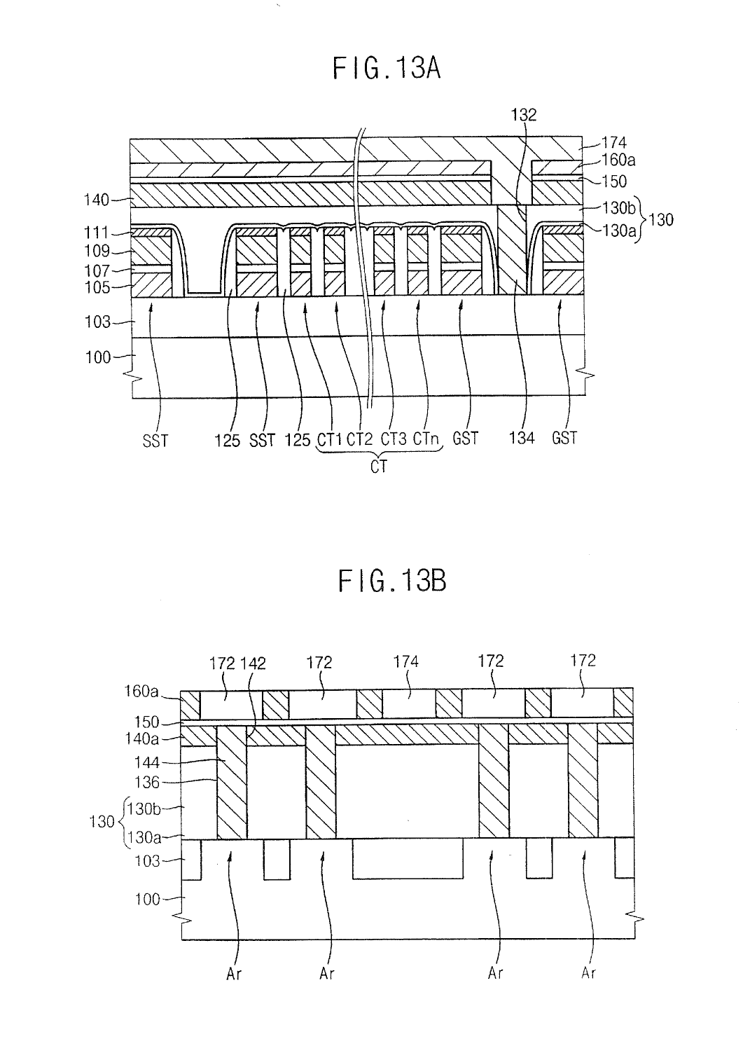

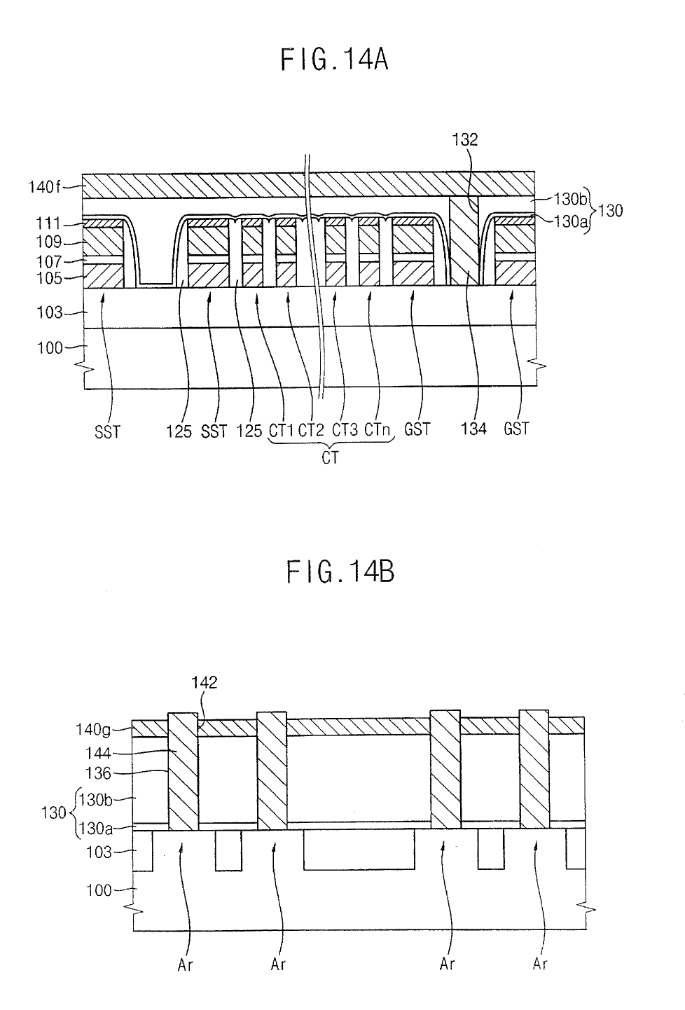

FIGS. 14A to 15B are cross-sections illustrating processing steps in the fabrication of flash memory devices including the conductive line illustrated in Figure in accordance with some embodiments of the present invention. FIGS. 14A and 15A are cross-sections taken along a line I-I of FIG. 7, and FIGS. 14B and 15B are cross-sections taken along a line II-II′ of FIG. 7. The processing steps for manufacturing the flash memory device including the conductive wiring 91 in FIG. 4 are substantially the same as those for manufacturing the flash memory device including the conductive wiring 90 in FIG. 3 discussed above with respect to FIGS. 9A to 13B, except for the processing step for forming the first insulation interlayer pattern and the processing step for forming the etch-stop layer. Therefore, details with respect to the processing steps for forming the first insulation interlayer pattern and the etch-stop layer will not be repeated herein.

Referring now to FIGS. 7, 14A and 14B, the second conductive layer is partially removed from the substrate 100, to thereby form a protruded contact plug 144 that is protruded from the first insulation interlayer pattern 140a. A first planarization process, such as a CMP process, and an etch-back process is performed on the first conductive layer until the first insulation interlayer pattern 140a is exposed, so that the first conductive layer remains only in the second contact hole 136 and the first via hole 142. A second planarization process may be performed on flat top surface of the contact plug 144 and the first insulation interlayer pattern 140a, to thereby form a reduced pattern 140g on the substrate 10. An upper portion of the first insulation interlayer pattern 140a is removed from the substrate 100 by the second planarization process, and thus an upper sidewall C of the contact plug 144 is exposed to surroundings. Slurry for the second planarization process is controlled to have such composition that only the first insulation interlayer pattern 140a is removed from the substrate 100 without any removal of the contact plug 144. Therefore, the size of the exposed sidewall C of the contact plug 144 is determined in accordance with processing time and velocity of the second planarization process.

Referring now to FIGS. 7, 15A and 15B, minute particles such as atoms and molecules are implanted onto the substrate 100 including the contact plug 144 and the reduced pattern 140g, to thereby form an etch-stop layer 150 on the contact plug 144 and the reduced pattern 140g. The processing step for forming the etch-stop layer 150 using the minute particles is substantially the same processing step as described with reference to FIG. 5D, so that any detailed descriptions on the formation step of the etch-stop layer will not be repeated herein.

Subsequent processing steps are performed on the etch-stop layer 150 in substantially the same method as described with reference to FIGS. 12A to 13B, to thereby form the flash memory device including the conductive wiring 91 illustrated in FIG. 4. Accordingly, the flash memory device may have an enlarged contact area between the bit line 172 and the contact plug 144 as large as the exposed sidewall C of the contact plug 144, thereby improving electrical reliability of the flash memory device.

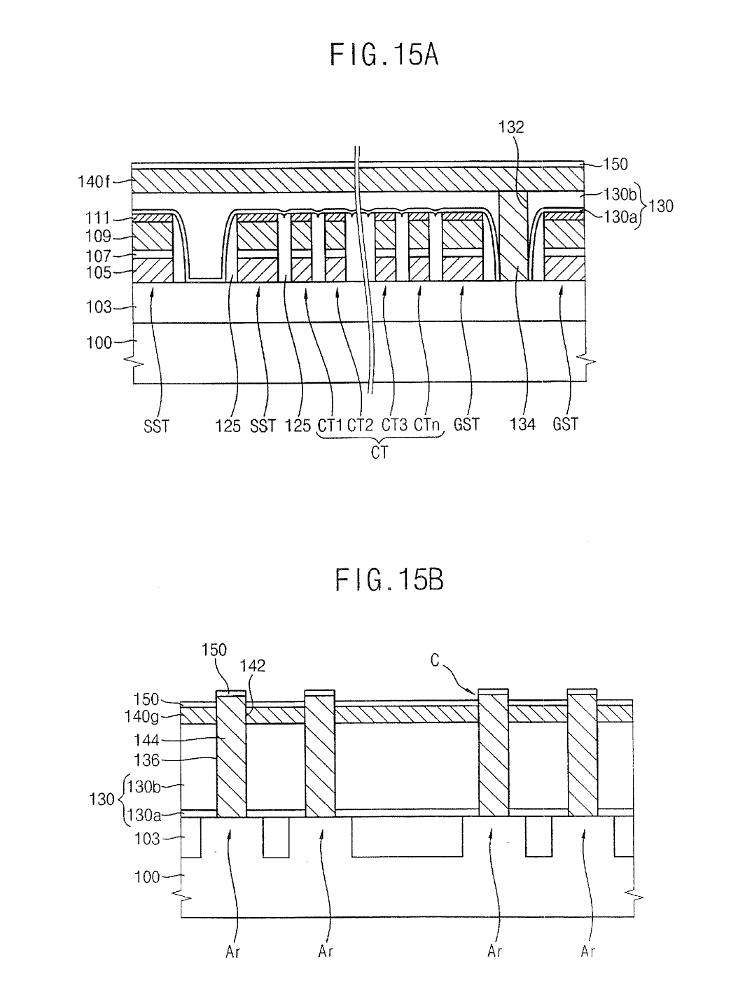

Referring now to FIG. 16, a graph showing variation of an effective dielectric constant K_{eff} of the flash memory device in relation to the thickness of the bit line including the etch-stop layer including silicon nitride (SiN) will be discussed. As illustrated in FIG. 16, the horizontal line indicates the thickness of the bit line of the flash memory device, and the vertical line indicates the effective dielectric constant K_{eff} of the flash memory device that is influenced by the parasitic capacitance of the bit line caused by the etch-stop layer in the bit line. The effective dielectric constant K_{eff} of the flash memory device was measured by varying the thickness of the etch-stop layer including silicon nitride (SiN). Each of the lines in the graph in FIG. 16 is distinguished from one another in accordance with the thickness of the etch-stop layer of the bit line. Table 1 illustrates the effective dielectric constant K_{eff} of the flash memory device when the bit line of the flash memory device has the thickness of from 1,000 Å and 600 Å, respectively in case that the etch-stop layer has the thickness of from 350 Å and about 50 Å.

TABLE 1

| | SiN 350 | SiN 50 |
|---|---|---|
| Bit line thickness of about 1,000 Å | 5.83 | 3.97 |
| Bit line thickness of about 600 Å | 7.42 | 3.99 |

Referring to FIG. 16 and Table 1, when the etch-stop layer of the bit line includes silicon nitride and had a thickness of about 350 Å, the thickness reduction of the bit line from about 1,000 Å to about 600 Å unexpectedly increased the effective dielectric constant K_{eff} of the flash memory from about 5.83 to about 7.42. Therefore, when the height of the bit line of the flash memory device decreases in accordance with a recent trend of high integration degree of the memory device, the parasitic capacitance in the bit line is unexpectedly increased, and thus the operation speed of the flash memory device is decreased due to the increased parasitic capacitance. However, when the thickness of the etch-stop layer was reduced from 350 Å to about 50 Å simultaneously with the thickness reduction of the bit line from about 1,000 Å to about 600 Å, the effective dielectric constant K_{eff} of the flash memory was remarkably decreased from about 5.83 to about 3.99. Accordingly, Table 1 shows that the thickness reduction of the etch-stop layer simultaneously with the thickness reduction of the bit line improves the effective dielectric constant K_{eff} of the flash memory device by as much as about 46%. As a result, operation performance of the flash memory device is remarkably improved under the condition that the thickness of the etch-stop layer is reduced as well as the thickness of the in the bit line including the etch-stop layer.

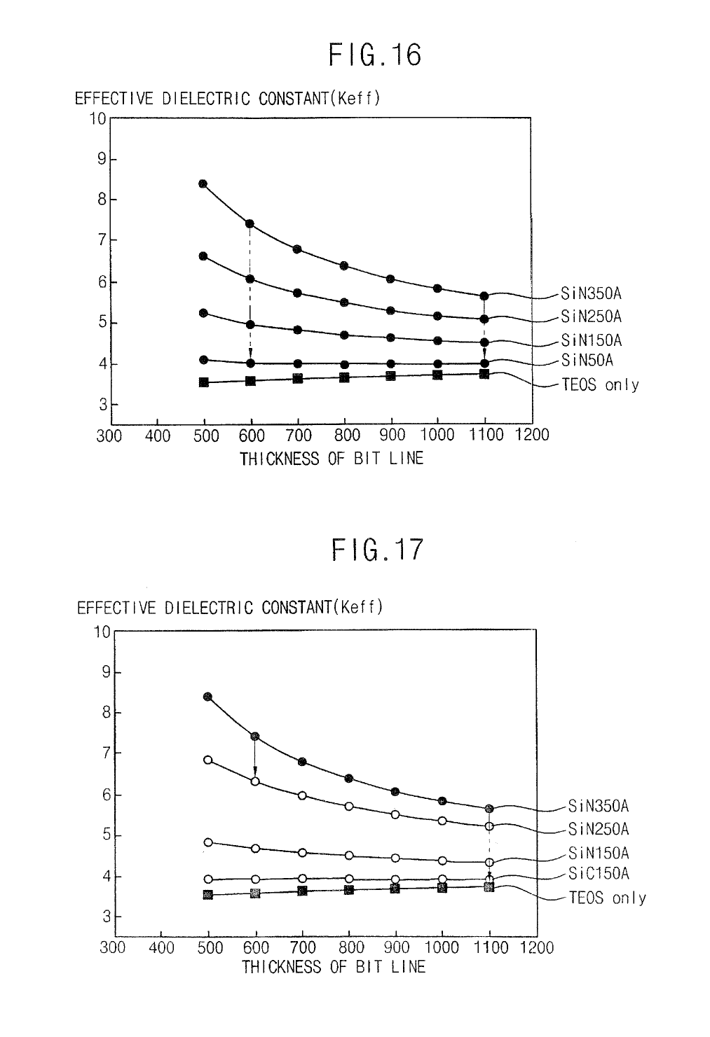

Referring now to FIG. 17, a graph showing variation of an effective dielectric constant K_{eff} of the flash memory device in relation to the thickness of the bit line including the etch-stop layer including silicon nitride (SiN) and silicon carbide (SiC) will be discussed. As illustrated in FIG. 17, the horizontal line indicates the thickness of the bit line of the flash memory device, and the vertical line indicates the effective dielectric constant K_{eff} of the flash memory device that is influenced by the parasitic capacitance of the bit line caused by the etch-stop layer in the bit line. The effective dielectric constant K_{eff} of the flash memory device was measured by varying the thickness and the composition of the etch-stop layer. Each of the lines in the graph in FIG. 17 is distinguished from one another in accordance with the thickness and the composition of the etch-stop layer. Table 2 exemplarily shows the effective dielectric constant K_{eff} of the flash memory device when the bit line of the flash memory device has a thickness of about 1,000 Å and 600 Å, respectively, in case that the etch-stop layer has substantially the same thickness of about 350 Å with different compositions of silicon nitride (SiN) and silicon carbide (SiC) and in case that the etch-stop layer has a thickness of about 50 Å with the composition of silicon carbide (SiC).

TABLE 2

| | SiN 350 | SiC 350 | SiC 50 |
|---|---|---|---|
| Bit line thickness of about 1,000 Å | 5.83 | 5.34 | 3.93 |
| Bit line thickness of about 600 Å | 7.42 | 6.33 | 3.94 |

FIG. 17 and Table 2 show that the composition change of the etch-stop layer from silicon nitride (SiN) to silicon carbide (SiC) improves the effective dielectric constant K_{eff} of the flash memory device at substantially the same thickness of the bit line. In particular, the thickness reduction of the bit line accelerates the improvement on the effective dielectric constant K_{eff}. When the thickness of the bit line is about 1,000 Å, the effective dielectric constant K_{eff} decreases from about 5.83 to about 5.34 by about 8.4%, however, when the thickness of the bit line is about 600 Å, the effective dielectric constant K_{eff} decreases from about 7.42 to about 6.33 by about 15%. As a result, silicon carbide (SiC) is much more suitable to the etch-stop layer of the bit line than silicon nitride (SiN).

Furthermore, the comparison between Table 1 and Table 2 indicates that the variation of the effective dielectric constant K_{eff} is much more sensitive to the thickness reduction of the bit line when the etch-stop layer includes silicon nitride than when the etch-stop layer includes silicon carbide. That is, when the etch-stop layer has the thickness of about 350 Å, the amount of the K_{eff} variation is about 1.59 in case that the etch-stop layer includes silicon nitride (SiN), while about 0.99 in case that the etch-stop layer includes silicon carbide (SiC). In the same way, when the etch-stop layer has the thickness of about 50 Å, the amount of the K_{eff} variation is about 0.02 in case that the etch-stop layer includes silicon nitride (SiN), while about 0.01 in case that the etch-stop layer includes silicon carbide (SiC). Accordingly, carbide, rather than nitride, is much better for prevention of the parasitic capacitance and for increase of the operation performance.

According some embodiments of the present invention, an etch-stop layer between first and second insulation interlayer patterns has a remarkably small thickness, so that parasitic capacitance caused by an etch-stop layer having a high dielectric constant may be sufficiently prevented despite a thickness reduction of a conductive line on the contact plug. Furthermore, the etch-stop layer has a high layer density by using an ion implantation process, and thus may have a sufficiently strong etch-resistance during an etching process for forming other trenches in a subsequent damascene process. Furthermore, an additional process for removing the etch-stop layer is not needed in a damascene process for forming the conductive line, thereby simplifying the damascene process.

Although the exemplary embodiments of the present invention have been described, it is understood that the present invention should not be limited to these exemplary embodiments but various changes and modifications can be made by one skilled in the art within the spirit and scope of the present invention as hereinafter claimed.

1. A conductive wiring for a semiconductor device, comprising:
a semiconductor substrate;
a plurality of lower conductive structures on the semiconductor substrate;
an insulating layer that electrically insulates the plurality of lower conductive structures from one another;
a first insulation interlayer pattern on the insulation layer, the first insulation interlayer pattern including a contact plug that contacts the substrate through the insulation layer;
an etch-stop layer on the contact plug and the first insulation interlayer pattern; and
a second insulation interlayer pattern on the etch-stop layer, the second insulation interlayer pattern including a conductive line that is electrically connected to the contact plug.

2. The conductive wiring of claim 1, wherein the first insulation interlayer pattern comprises at least one of borophosphosilicate (BPSG), phosphosilicate glass (PSG), fluorosilicate glass (FSG), plasma-enhanced tetraethylorthosilicate (PE-TEOS) and undoped silicate glass (USG).

3. The conductive wiring of claim 2, wherein the contact plug comprises:
a single layer including a polysilicon layer or a metal layer; or
a multilayer including the polysilicon layer and the metal layer sequentially stacked.

4. The conductive wiring of claim 3, wherein the metal layer comprises a tungsten (W) layer or an aluminum (Al) layer.

5. The conductive wiring of claim 1, wherein the first insulation interlayer pattern has a thickness of from about 4,000 Å to about 5,000 Å on a surface of the substrate.

6. The conductive wiring of claim 1, wherein the etch-stop layer comprises carbon (C) or nitrogen (N) implanted into surfaces of the first insulation interlayer pattern and the contact plug.

7. The conductive wiring of claim 6, wherein the etch-stop layer comprises at least one of silicon carbide (SiC), silicon nitride (SiN), silicon oxynitride (SiON) and silicon oxycarbide (SiOC) and has etching selectivity with respect to the second insulation interlayer pattern.

8. The conductive wiring of claim 6, wherein the contact plug protrudes from a surface of the first insulation interlayer pattern such that the etch-stop layer is discontinuous at a boundary portion of the first insulation interlayer pattern and the contact plug.

9. The conductive wiring of claim 1, wherein the etch-stop layer comprises a thickness of from about 50 Å to about 200 Å from a surface of the first insulation interlayer pattern.

10. The conductive wiring of claim 1, wherein the second insulation interlayer pattern comprises at least one of BPSG, PSG, FSG, PE-TEOS, and USG.

11. The conductive wiring of claim 10, wherein the second insulation interlayer pattern comprises a same material as the first insulation interlayer pattern.

12. The conductive wiring of claim 1, wherein the conductive line includes copper (Cu), tungsten (W) and/or aluminum (Al).

13. The conductive wiring of claim 12, wherein the second insulation interlayer pattern comprises a single damascene pattern.

14. The conductive wiring of claim 1, wherein the conductive line has a thickness of from about 400 Å to about 700 Å from a surface of the etch-stop layer, and a surface of the conductive line is coplanar with that of the second insulation interlayer pattern.

15. The conductive wiring of claim 1:
wherein the substrate comprises a device isolation layer defining an active region that extends in a first direction; and
wherein the plurality of lower conductive structures comprise a string selection transistor, a plurality of cell selection transistors and a ground selection transistor on an active region of the semiconductor substrate such that the string selection transistor, the plurality of the cell selection transistors, and a plurality of the ground selection transistors are arranged along a second direction perpendicular to the first direction to thereby function as a string selection line (SSL), a plurality of word lines (WLs) and a ground selection line (GSL) of a flash memory device, respectively.

16-53. (canceled)
